(19) United States
(12) Patent Application Publication
(10) Pub. No.: US 2026/0324297 A1
(43) Pub. Date: Oct. 15, 2026

(54) ELECTRONIC CIRCUIT AND COMPUTING DEVICE

(71) Applicant: Kabushiki Kaisha Toshiba, Kawasaki-shi Kanagawa (JP)

(72) Inventors: Yinghao HO, Kawasaki Kanagawa (JP); Kentaro KUBO, Kawasaki Kanagawa (JP); Hayato GOTO, Kawasaki Kanagawa (JP); Tamio KAWAGUCHI, Kawasaki Kanagawa (JP); Noritsugu SHIOKAWA, Kawasaki Kanagawa (JP)

(73) Assignee: Kabushiki Kaisha Toshiba, Kawasaki-shi Kanagawa (JP)

(21) Appl. No.: 19/460,976

(22) Filed: Jan. 27, 2026

Related U.S. Application Data
(63) Continuation of application No. PCT/JP2024/042687, filed on Dec. 3, 2024.

(30) Foreign Application Priority Data
Mar. 4, 2024 (JP) 2024-032254
Nov. 18, 2024 (JP) 2024-200888

(51) Int. Cl. H10N 60/12; G06N 10/40; H10N 60/01; H10N 60/80; H10N 60/82; H10N 60/83; H10N 99/00

(52) U.S. Cl. CPC H10N 60/12; G06N 10/40; H10N 60/0912; H10N 60/805; H10N 60/82; H10N 60/83; H10N 99/05

(57) ABSTRACT

According to one embodiment, an electronic circuit includes a first structure. The first structure includes first to third Josephson junctions, and first to third conductive portions. 1/2 of a sum of a second frequency and a third frequency is smaller than a first frequency. The second frequency corresponds to a first excited state of the first structure when a magnetic flux passes through a space surrounded by a loop including the first Josephson junction, the second Josephson junction, the third Josephson junction, the first conductive portion, the second conductive portion, and the third conductive portion is zero. The third frequency corresponds to a second excited state of the first structure when the magnetic flux is zero. The first frequency corresponds to the second excited state when the magnetic flux is 0.5 times a magnetic flux quantum.

### CROSS-REFERENCE TO RELATED APPLICATIONS

This is a continuation application of International Application PCT/JP2024/042687, filed on Dec. 3, 2024. This application also claims priority to Japanese Patent Application No. 2024-032254, filed on Mar. 4, 2024, and Japanese Patent Application No. 2024-200888, filed on Nov. 18, 2024. The entire contents of which are incorporated herein by reference.

### FIELD

Embodiments described herein relate generally to an electronic circuit and a computing device.

### BACKGROUND

For example, electronic circuits including multiple nonlinear elements are used in computing devices. Improvements in performance are desired in electronic circuits and computing devices.

### BRIEF DESCRIPTION OF THE DRAWINGS

FIG. 1 is a schematic diagram illustrating an electronic circuit according to a first embodiment;

FIG. 2 is a graph illustrating the characteristics of the electronic circuit according to the first embodiment;

FIG. 3 is a graph illustrating the characteristics of the electronic circuit according to a reference example;

FIGS. 4A and 4B are graphs illustrating the characteristics of the electronic circuit according to the first embodiment;

FIG. 5 is a graph illustrating the characteristics of the electronic circuit;

FIG. 6 is a graph illustrating the operation of the electronic circuit according to the first embodiment;

FIG. 7 is a graph illustrating the operation of the electronic circuit according to the first embodiment;

FIG. 8 is a graph illustrating the characteristics of the electronic circuit according to the first embodiment;

FIG. 9 is a graph illustrating the characteristics of the electronic circuit according to the second embodiment;

FIG. 10 is a schematic diagram illustrating a computing device according to the second embodiment;

FIG. 11 is a schematic plan view illustrating an electronic circuit and computing device according to the embodiment;

FIGS. 12A and 12B are schematic diagrams illustrating an electronic circuit and a computing device according to the embodiment;

FIGS. 13A and 13B are schematic diagrams illustrating an electronic circuit and a computing device according to the embodiment;

FIG. 14 is a schematic plan view illustrating an electronic circuit according to the embodiment;

FIG. 15 is a schematic diagram illustrating an electronic circuit according to a third embodiment;

FIG. 16 is a schematic diagram illustrating an electronic circuit according to the third embodiment;

FIG. 17 is a schematic plan view illustrating an electronic circuit according to a fourth embodiment;

FIGS. 18A and 18B are schematic views illustrating an electronic circuit according to the fourth embodiment;

FIGS. 19A to 19C are schematic views illustrating an electronic circuit according to a fifth embodiment;

FIGS. 20A to 20C are schematic views illustrating an electronic circuit according to the fifth embodiment;

FIG. 21 is a schematic cross-sectional view illustrating an electronic circuit according to the fifth embodiment;

FIGS. 22A to 22I are schematic cross-sectional views illustrating a method for manufacturing an electronic circuit according to the fifth embodiment;

FIGS. 23A to 23I are schematic cross-sectional views illustrating a method for manufacturing an electronic circuit according to the fifth embodiment;

FIG. 24 is a schematic view illustrating an electronic circuit according to a sixth embodiment;

FIG. 25 is a circuit diagram illustrating an electronic circuit according to the sixth embodiment;

FIG. 26 is a schematic plan view illustrating an electronic circuit according to the sixth embodiment;

FIG. 27 is a schematic diagram illustrating the electronic circuit according to the sixth embodiment;

FIG. 28 is a schematic plan diagram illustrating an electronic circuit according to the seventh embodiment;

FIGS. 29A and 29B are schematic views illustrating a computing device according to the eighth embodiment;

FIGS. 30A and 30B are schematic views illustrating a computing device according to the eighth embodiment;

FIGS. 31A and 31B are schematic views illustrating a computing device according to the eighth embodiment; and

FIGS. 32A and 32B are schematic diagrams illustrating a computing device according to the eighth embodiment.

### DETAILED DESCRIPTION

According to one embodiment, an electronic circuit includes a first structure. The first structure includes a first Josephson junction including a first end and a first other end, a second Josephson junction including a second end and a second other end; a third Josephson junction including a third end and a third other end, a first conductive portion configured to be coupled with the first other end and the third end, a second conductive portion configured to be coupled with the second other end and the third other end; and a third conductive portion configured to be coupled to the first end and the second end. half of a sum of a second frequency and a third frequency is smaller than a first frequency. The second frequency corresponds to a first excited state of the first structure when a magnetic flux passes through a space surrounded by a loop including the first Josephson junction, the second Josephson junction, the third Josephson junction, the first conductive portion, the second conductive portion, and the third conductive portion is zero. The third frequency corresponds to a second excited state of the first structure when the magnetic flux is zero. The first frequency corresponds to the second excited state when the magnetic flux is 0.5 times a magnetic flux quantum.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

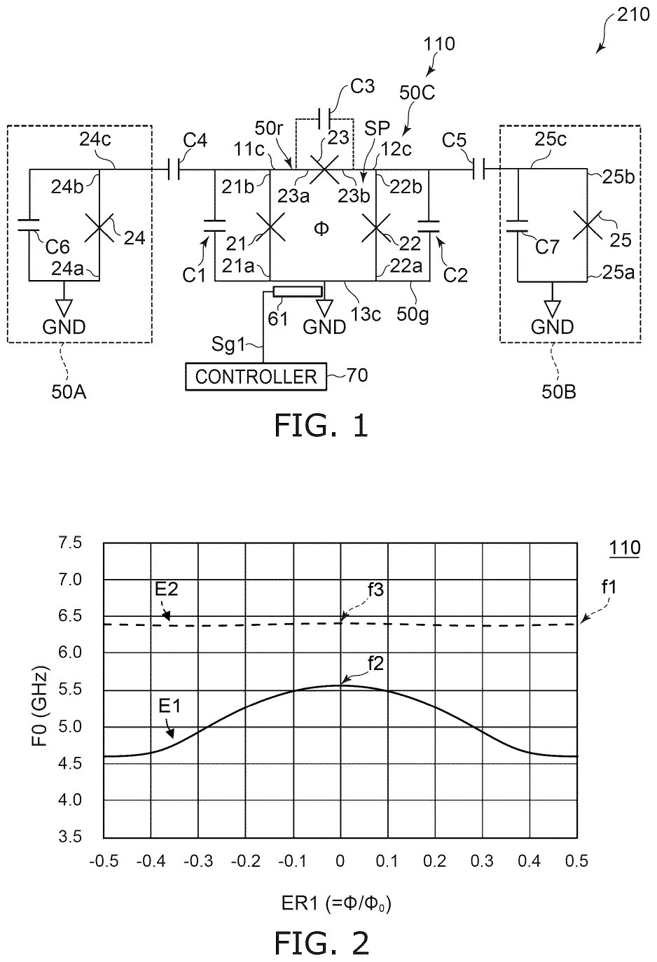

FIG. 1 is a schematic diagram illustrating an electronic circuit according to a first embodiment.

FIG. 2 is a graph illustrating the characteristics of the electronic circuit according to the first embodiment.

As shown in FIG. 1, an electronic circuit 110 according to the embodiment includes a first structure 50C.

The first structure 50C includes a first Josephson junction 21, a second Josephson junction 22, a third Josephson junction 23, a first conductive portion 11c, a second conductive portion 12c, and a third conductive portion 13c. The first Josephson junction 21 includes a first end 21a and a first other end 21b. The second Josephson junction 22 includes a second end 22a and a second other end 22b. The third Josephson junction 23 includes a third end 23a and a third other end 23b.

The first conductive portion 11c is configured to be coupled with the first other end 21b and the third end 23a. The second conductive portion 12c is configured to be coupled with the second other end 22b and the third other end 23b. The third conductive portion 13c is configured to be coupled with the first end 21a and the second end 22a.

The first structure 50C, for example, couples with a first qubit 50A and a second qubit 50B. The electronic circuit 110 is, for example, a variable coupler. The electronic circuit 110 is, for example, a double-transmon coupler.

For example, the magnetic flux Φ passing through a space SP surrounded by a loop 50r including the first Josephson junction 21, the second Josephson junction 22, the third Josephson junction 23, the first conductive portion 11c, the second conductive portion 12c, and the third conductive portion 13c is controlled. For example, a first conductive member 61 is supplied with the signal Sg1. The signal Sg1 is a current pulse or the like. A magnetic field based on the signal Sg1 is applied to the space SP in the loop 50r. The magnetic flux Φ is controlled by the magnetic field.

The horizontal axis in FIG. 2 is a magnetic flux ratio ER1. The magnetic flux ratio ER1 is a ratio of the magnetic flux Φ to the magnetic flux quantum Φ₀. The vertical axis in FIG. 2 is a frequency F0. The frequency F0 corresponds to energy level of an excited state.

As shown in FIG. 2, the first structure 50C has multiple excited states. The plurality of excited states include a first excited state E1 and a second excited state E2. The excited state can be controlled by the magnetic flux Φ.

As shown in FIG. 2, the first structure 50C has a first frequency f1, a second frequency f2, and a third frequency f3. The second frequency f2 corresponds to the energy level of the first excited state E1 of the first structure 50C when the magnetic flux Φ passing through the space SP surrounded by the loop 50r is zero. The third frequency f3 corresponds to the energy level of the second excited state E2 of the first structure 50C when the magnetic flux Φ is zero. The first frequency f1 corresponds to the energy level of the second excited state E2 when the magnetic flux Φ is 0.5 times the magnetic flux quantum Φ₀ (when the magnetic flux ratio ER1 is 0.5).

As shown in FIG. 2, for example, half of the sum of the second frequency f2 and the third frequency f3 is smaller than the first frequency f1. The half of the sum of the second frequency f2 and the third frequency f3 corresponds to the average of the second frequency f2 and the third frequency f3.

As described later, in the embodiment, a sufficiently small residual ZZ coupling strength can be obtained even when the magnetic flux Φ is close to zero. For example, the residual ZZ coupling strength can be suppressed to 10 kHz or less. Thereby, for example, it is possible to control the ZZ coupling strength using the alternating current signal Sg1 in which the direct current (DC) component is substantially zero.

For example, it is possible to perform a two-qubit gate operation using a signal Sg1 that does not include a DC component. This two-qubit gate operation corresponds to a CZ gate. For example, the influence of noise such as heat from the outside can be suppressed. Thereby, highly accurate control can be possible. According to the embodiment, it is possible to provide an electronic circuit whose characteristics can be improved.

For example, a difference between half of the sum of the second frequency f2 and the third frequency f3, and the first frequency f1 is defined as a frequency difference Δf. The frequency difference Δf is {(f2+f3)/2}−f1. In the embodiment, the frequency difference Δf is negative.

The characteristics illustrated in FIG. 2 can be obtained, for example, by optimizing the configuration of the electronic circuit 110.

As shown in FIG. 1, a first capacitance C1 is formed between the first conductive portion 11c and the third conductive portion 13c. A second capacitance C2 is formed between the second conductive portion 12c and the third conductive portion 13c. A third capacitance C3 is formed between the first conductive portion 11c and the second conductive portion 12c.

In the embodiment, for example, the third capacitance C3 is greater than 0.2 times the first capacitance C1. For example, the third capacitance C3 is greater than 0.2 times the second capacitance C2. As a result, the frequency difference Δf tends to become negative.

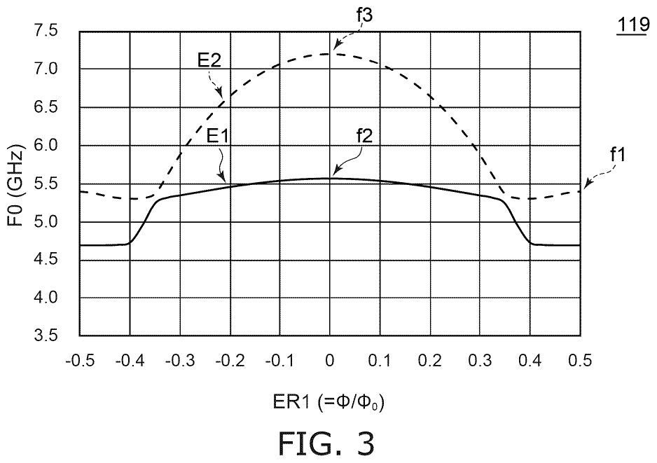

FIG. 3 is a graph illustrating the characteristics of the electronic circuit according to a reference example.

FIG. 3 illustrates the characteristics of the electronic circuit 119 according to a reference example. In the electronic circuit 119, the third capacitance C3 is less than or equal to 0.2 times the first capacitance C1 and less than or equal to 0.2 times the second capacitance C2. As shown in FIG. 3, in the electronic circuit 119 according to the reference example, the frequency difference Δf is positive.

In the reference example, by shifting the magnetic flux ratio ER1 to about 0.35 in a DC manner, the residual ZZ coupling strength becomes sufficiently small. In the reference example, an external coil and a DC power source are provided, for example, in order to shift the magnetic flux ratio ER1 to about 0.35. As a result, the circuit tends to be susceptible to external noise such as heat.

In contrast, in the embodiment, a sufficiently small residual ZZ coupling strength can be obtained even when the magnetic flux Φ is close to zero. For example, the residual ZZ coupling strength can be suppressed to 10 kHz or less. The external coil and DC power supply in the reference example are not required, and the influence of noise such as heat from the outside tends not to be generated. Thereby, for example, the ZZ coupling strength between two qubits coupled with the electronic circuit 110 according to the embodiment can be controlled by the alternating current signal Sg1 with substantially zero direct current component.

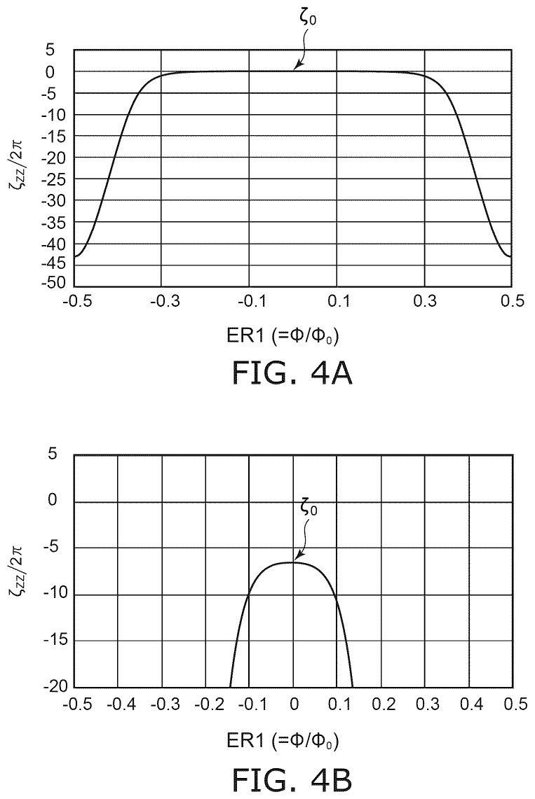

FIGS. 4A and 4B are graphs illustrating the characteristics of the electronic circuit according to the first embodiment.

The horizontal axis of these figures is the magnetic flux ratio ER1. The vertical axis is the ZZ coupling strength ζ_{zz}. FIG. 4B shows an enlarged part of FIG. 4A. As shown in FIGS. 4A and 4B, a sufficiently small ZZ coupling strength ζ_{zz} is obtained at a low magnetic flux ratio ER1. The coupled qubits can be operated at low flux ratios ER1. As shown in FIGS. 4A and 4B, the ZZ coupling strength ζ_{zz} when the magnetic flux Φ is zero is defined as a residual ZZ coupling strength ζ₀. In this example, the absolute value of the residual ZZ coupling strength ζ₀/2π is 7 kHz or less. “π” is pi.

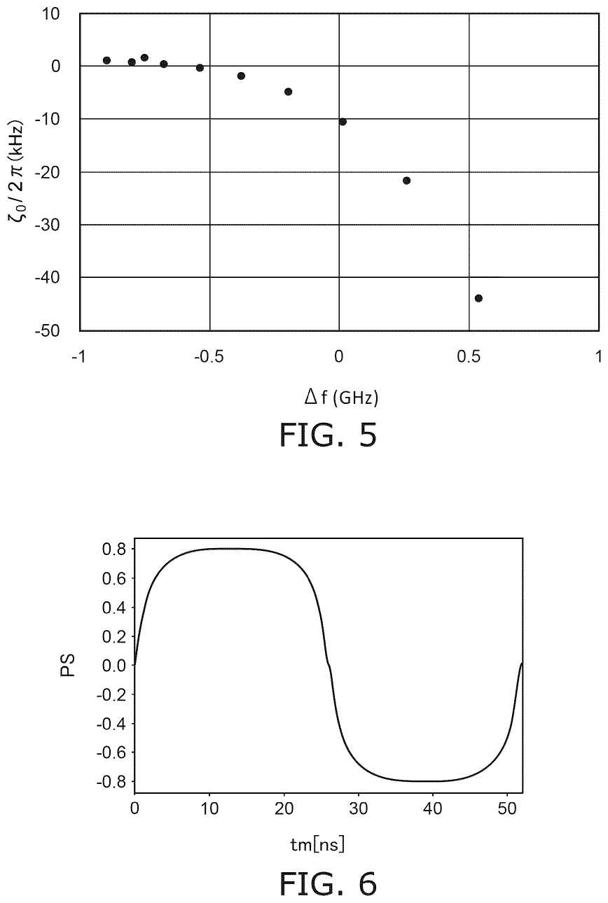

FIG. 5 is a graph illustrating the characteristics of the electronic circuit.

The horizontal axis in FIG. 5 is the frequency difference Δf. As already explained, the frequency difference Δf is {(f2+f3)/2}−f1. The vertical axis is the residual ZZ coupling strength ζ₀. As already explained, the residual ZZ coupling strength ζ₀ is the ZZ coupling strength ζzz when the magnetic flux Φ is zero. As shown in FIG. 5, when the frequency difference Δf is negative, the absolute value of the residual ZZ coupling strength ζ₀ is relatively small. In the embodiment, when the frequency difference Δf is negative, a small residual ZZ coupling strength ζ₀ is obtained when the magnetic flux Φ is zero. When the frequency difference Δf is negative, the ZZ coupling strength between qubits can be controlled using a signal Sg1 that does not include a DC component.

In the embodiment, when the frequency difference Δf is negative and the absolute value of the frequency difference Δf increases, the absolute value of the residual ZZ coupling strength ζ₀ decreases. The frequency difference Δf is negative, and the absolute value of the frequency difference Δf may be 0.5 GHz or more. A small absolute value of the residual ZZ coupling strength ζ₀ is obtained. In the embodiment, the absolute value of the frequency difference Δf may be, for example, 20 GHz or less.

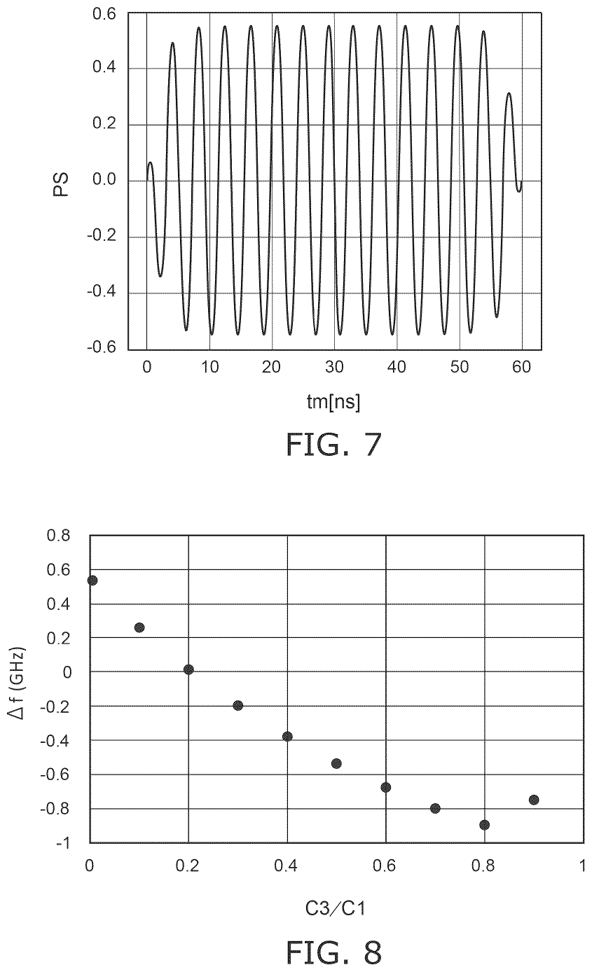

FIGS. 6 and 7 are graphs illustrating the operation of the electronic circuit according to the first embodiment.

These figures illustrate the signal Sg1. The horizontal axis is time tm. The vertical axis is the strength PS of the signal Sg1. As shown in FIG. 6, the signal Sg1 includes a positive pulse and a negative pulse. The absolute value of the strength PS of the positive pulse may be substantially the same as the absolute value of the strength PS of the negative pulse. As shown in FIG. 7, the signal Sg1 may be an AC signal. The DC component of the signal Sg1 may be substantially zero.

In the embodiment, the first frequency f1 may be, for example, not less than 1 GHz and not more than 20 GHz. The second frequency f2 may be, for example, not less than 1 GHz and not more than 20 GHz. For example, the third frequency f3 may be not less than 1 GHz and not more than 20 GHz.

FIG. 8 is a graph illustrating the characteristics of the electronic circuit according to the first embodiment.

The horizontal axis in FIG. 8 is a first capacitance ratio C3/C1. The vertical axis is the frequency difference Δf. As can be seen from FIG. 8, as the first capacitance ratio C3/C1 increases, the frequency difference Δf becomes negative and the absolute value of the frequency difference Δf increases. When the first capacitance ratio C3/C1 is 0.2 or more, the frequency difference Δf becomes lower than 0.

In the embodiment, for example, the third capacitance C3 is preferably equal to or greater than 0.2 times the first capacitance C1. For example, the third capacitance C3 is preferably 0.2 times or more the second capacitance C2. For example, it is more preferable that the third capacitance C3 is 0.3 times or more the first capacitance C1. For example, it is more preferable that the third capacitance C3 is 0.3 times or more the second capacitance C2. For example, the third capacitance C3 may be 10 times or less the first capacitance C1. For example, the third capacitance C3 may be 10 times or less the second capacitance C2. For example, when the third capacitance C3 is excessively large, the size of the circuit tends to increase.

In the embodiment, for example, the electronic circuit 110 is a double-transmon coupler. In the electronic circuit 110, when the magnetic flux Φ being externally applied is zero, the residual ZZ coupling strength ζ₀ can be sufficiently reduced. For example, the ZZ coupling strength can be controlled by the signal Sg1 that does not substantially include a DC component. By not requiring a DC component, for example, the influence of heat can be suppressed. For example, power can be reduced. For example, the influence of pulse distortion on the signal Sg1 can be suppressed.

For example, as shown in FIG. 2, the change in energy (frequency F0) is small near zero magnetic flux Φ. For example, coherence time becomes longer.

### Second Embodiment

As shown in FIG. 1, a computing device 210 according to the second embodiment includes the electronic circuit 110 according to the first embodiment, the first qubit 50A, and the second qubit 50B. The first qubit 50A is configured to be coupled with the first conductive portion 11c. The second qubit 50B is configured to be coupled with the second conductive portion 12c.

As shown in FIG. 1, a fourth capacitance C4 is formed between the first conductive portion 11c and the first qubit 50A. A fifth capacitance C5 is formed between the second conductive portion 12c and the second qubit 50B.

In the embodiment, the third capacitance C3 between the first conductive portion 11c and the second conductive portion 12c is preferably larger than three times the fourth capacitance C4. Preferably, the third capacitance C3 is greater than three times the fifth capacitance C5. This facilitates obtaining a negative frequency difference Δf.

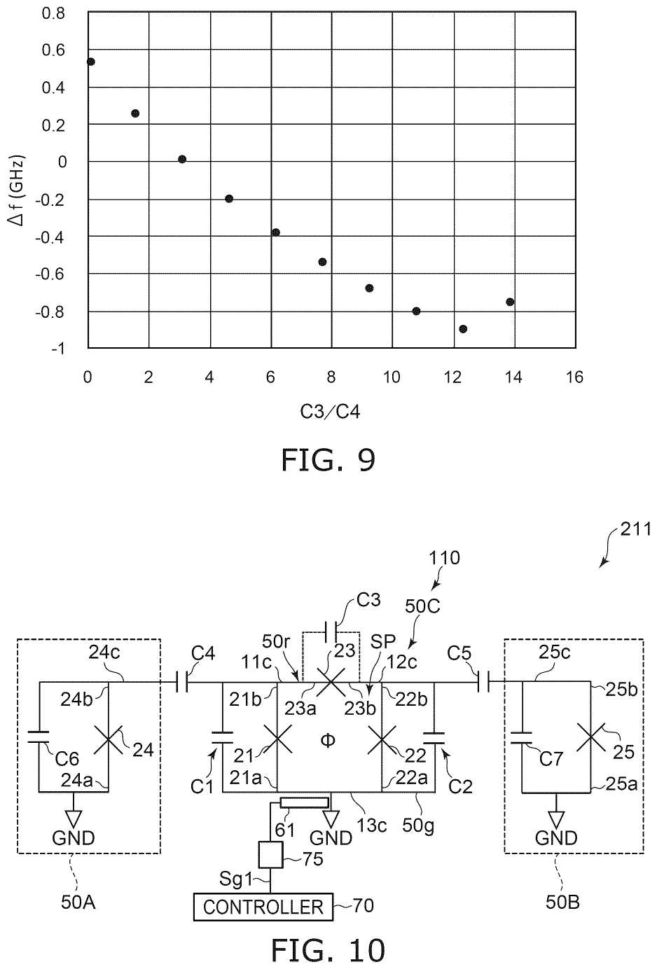

FIG. 9 is a graph illustrating the characteristics of the electronic circuit according to the second embodiment.

The horizontal axis in FIG. 9 is a second capacitance ratio C3/C4. The vertical axis is the frequency difference Δf. As can be seen from FIG. 9, as the second capacitance ratio C3/C4 increases, the frequency difference Δf decreases. In a region where the second capacitance ratio C3/C4 is higher than 3, the frequency difference Δf becomes lower than 0.

In the embodiment, the third capacitance C3 is preferably three times or more the fourth capacitance C4. It is preferable that the third capacitance C3 is three times or more the fifth capacitance C5. For example, the third capacitance C3 is preferably 50 times or less the fourth capacitance C4. For example, the third capacitance C3 is preferably 50 times or less the fifth capacitance C5. More preferably, the third capacitance C3 is 4.6 times or more the fourth capacitance C4. More preferably, the third capacitance C3 is 4.6 times or more the fifth capacitance C5.

As shown in FIG. 1, the computing device 210 according to the embodiment may further include a controller 70 (for example, control circuitry). The first structure 50C may further include a first conductive member 61. The controller 70 is configured to supply the signal Sg1 to the first conductive member 61 to control the magnetic flux Φ passing through the space SP.

As described with reference to FIGS. 6 and 7, the signal Sg1 includes, for example, a positive polarity signal and a negative polarity signal. The controller 70 may be configured to perform a two-qubit gate on the first qubit 50A and the second qubit 50B by supplying such a signal Sg1 to the first conductive member 61.

As shown in FIG. 1, the first qubit 50A includes, for example, a fourth Josephson junction 24 including a fourth end 24a and a fourth other end 24b. The fourth other end 24b is configured to be coupled with the first conductive portion 11c. The fourth end 24a may be configured to be coupled with the third conductive portion 13c. The third conductive portion 13c may function as, for example, a ground layer 50g (GND). The first qubit 50A may further include, for example, a fourth conductive portion 24c. The fourth other end 24b is electrically connected to the fourth conductive portion 24c. The fourth capacitance C4 is formed between the fourth conductive portion 24c and the first conductive portion 11c. The fourth conductive portion 24c may be configured to be coupled with the first conductive portion 11c.

As shown in FIG. 1, the second qubit 50B includes, for example, a fifth Josephson junction 25 including a fifth end 25a and a fifth other end 25b. The fifth other end 25b is configured to be coupled with the second conductive portion 12c. The fifth end 25a may be configured to be coupled with the third conductive portion 13c. The second qubit 50B may further include, for example, a fifth conductive portion 25c. The fifth other end 25b is electrically connected to the fifth conductive portion 25c. The fifth capacitance C5 is formed between the fifth conductive portion 25c and the second conductive portion 12c. The fifth conductive portion 25c may be configured to be coupled with the second conductive portion 12c.

As shown in FIG. 1, a sixth capacitance C6 may be formed between the fourth end 24a and the fourth other end 24b. A seventh capacitance C7 may be formed between the fifth end 25a and the fifth other end 25b.

FIG. 10 is a schematic diagram illustrating a computing device according to the second embodiment.

As shown in FIG. 10, a computing device 211 according to the embodiment further includes a high-pass filter 75. The configuration of the computing device 211 except for this may be the same as the configuration of the computing device 210. The high-pass filter 75 is provided between controller 70 and first conductive member 61. The high-pass filter 75 removes the DC component. For example, the magnetic flux Φ based on the alternating current component of signal Sg1 is effectively applied to space SP. Higher accuracy operation can be obtained.

Hereinafter, some examples of structures of electronic circuits and computing devices according to embodiments will be described.

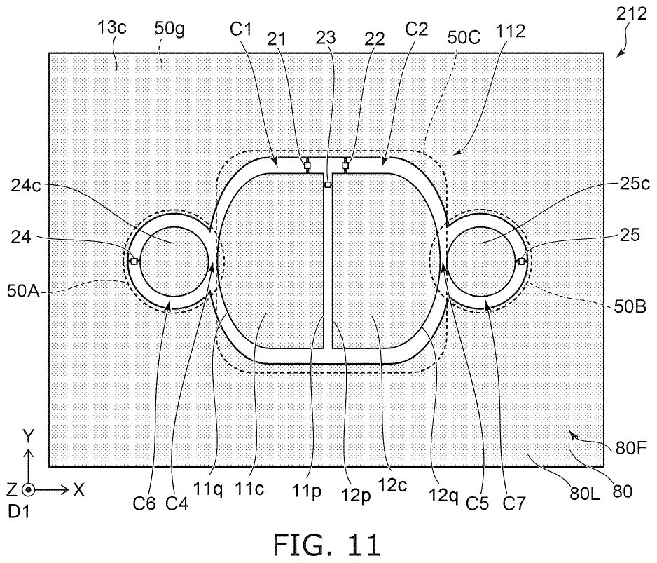

FIG. 11 is a schematic plan view illustrating an electronic circuit and computing device according to the embodiment.

As shown in FIG. 11, an electronic circuit 112 according to the embodiment includes the first Josephson junction 21, the second Josephson junction 22, the third Josephson junction 23, the first conductive portion 11c, the second conductive portion 12c, and the third conductive portion 13c are provided on a first face 80F of a base 80. In this example, the first qubit 50A and the second qubit 50B are also provided on first face 80F in a computing device 212 including the electronic circuit 112. The first conductive portion 11c, the second conductive portion 12c, and the third conductive portion 13c are based on a first conductive layer 80L provided on the first face 80F.

As shown in FIG. 11, in this example, the first conductive portion 11c includes a first facing portion 11p and a first other facing portion 11q. The first facing portion 11p faces the second conductive portion 12c. The first other facing portion 11q faces the fourth conductive portion 24c. The first facing portion 11p and the first other facing portion 11q may satisfy at least one of a first condition and a second condition. In the first condition, an area of the first facing portion 11p is larger than an area of the first other facing portion 11q. In the second condition, a first distance between the first facing portion 11p and the second conductive portion 12c is shorter than a second distance between the first other facing portion 11q and the fourth conductive portion 24c. With such a configuration, for example, the third capacitance C3 becomes larger than the fourth capacitance C4.

The second conductive portion 12c includes a second facing portion 12p and a second other facing portion 12q. The second facing portion 12p faces the first conductive portion 11c. The second other facing portion 12q faces the fifth conductive portion 25c. The second facing portion 12p and the second other facing portion 12q may satisfy at least one of a third condition and a fourth condition. In the third condition, an area of the second facing portion 12p is larger than an area of the second other facing portion 12q. In the fourth condition, a third distance between the second facing portion 12p and the first conductive portion 11c is shorter than a fourth distance between the second other facing portion 12q and the fifth conductive portion 25c. With such a configuration, for example, the third capacitance C3 becomes larger than the fifth capacitance C5.

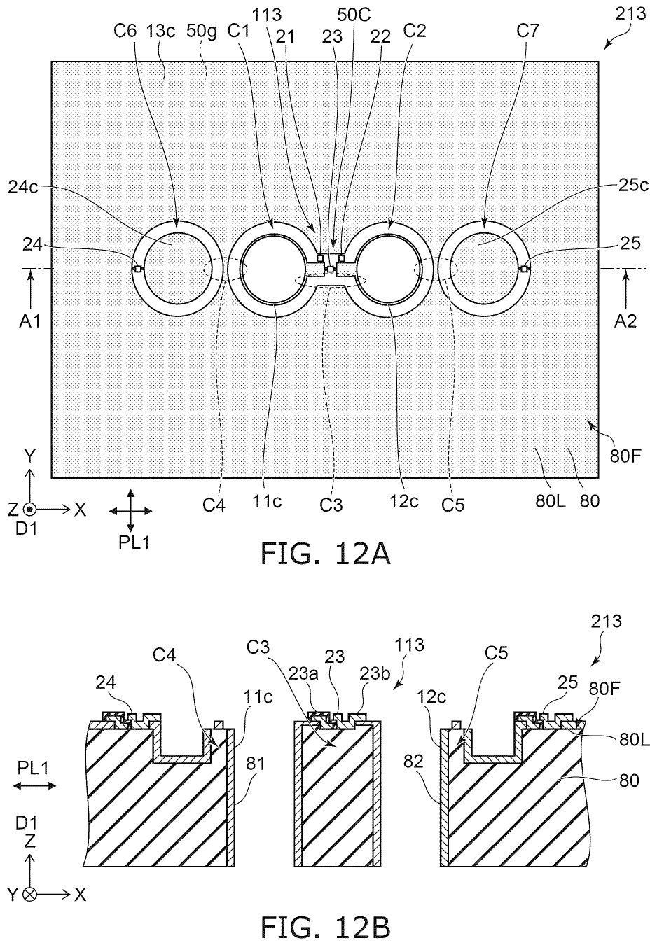

FIGS. 12A and 12B are schematic views illustrating an electronic circuit and a computing device according to the embodiment.

FIG. 12A is a plan view. FIG. 12B is a sectional view taken along the line A1-A2 in FIG. 12A. As shown in FIGS. 12A and 12B, in an electronic circuit 113 and a computing device 213 including the electronic circuit 113 according to the embodiment, the first structure 50C further includes the base 80. The base 80 includes a first face 80F and a first side face 81. The first side face 81 crosses a plane PL1 including the first face 80F. For example, the plane PL1 is along the X-Y plane. The first side face 81 crosses the X-Y plane. The third Josephson junction 23 is provided on the first face 80F. At least a part of the first conductive portion 11c is provided on the first side face 81. The configuration of the electronic circuit 110 (and computing device 210) except for this may be applied to the configuration of the electronic circuit 113 (and computing device 213).

By providing at least a part of the first conductive portion 11c on the first side face 81, the area of the electronic circuit 113 and the computing device 213 can be reduced. It becomes easy to downsize. By utilizing the side faces of the base 80, large capacitance can be obtained in a small face. The first side face 81 may be a side face of a hole passing through the base 80 in the Z-axis direction.

In the electronic circuit 113 and the computing device 213, the base 80 may further include a second side face 82. The second side face 82 crosses the plane PL1 including the first face 80F. At least a part of the second conductive portion 12c is provided on the second side face 82.

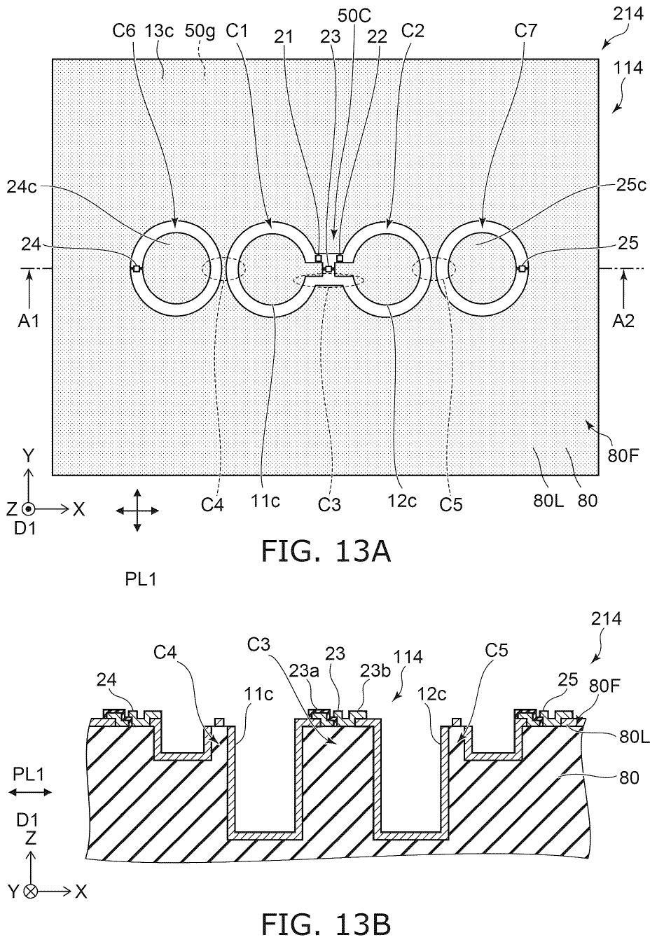

FIGS. 13A and 13B are schematic views illustrating an electronic circuit and a computing device according to the embodiment.

FIG. 13A is a plan view. FIG. 13B is a sectional view taken along the line A1-A2 in FIG. 13A. As shown in FIGS. 13A and 13B, in the electronic circuit 114 according to the embodiment and the computing device 214 including the electronic circuit 114 as well, the base 80 of the first structure 50C includes the first face 80F, the first side face 81 and the second side face 82. In this example, the first side face 81 and the second side face 82 are side faces of a recess provided in the base 80. The area of the electronic circuit 114 and the computing device 214 can also be reduced. It becomes easy to downsize. By utilizing the side faces of the base 80, large capacitance can be obtained in a small area.

The embodiments may include the following Technical proposals:
(Technical proposal 1)

An electronic circuit, comprising:
a first structure, the first structure including:
   a first Josephson junction including a first end and a first other end;
   a second Josephson junction including a second end and a second other end;
   a third Josephson junction including a third end and a third other end;
   a first conductive portion configured to be coupled with the first other end and the third end;
   a second conductive portion configured to be coupled with the second other end and the third other end; and
   a third conductive portion configured to be coupled to the first end and the second end,
half of a sum of a second frequency and a third frequency being smaller than a first frequency,
the second frequency corresponding to a first excited state of the first structure when a magnetic flux passing through a space surrounded by a loop including the first Josephson junction, the second Josephson junction, the third Josephson junction, the first conductive portion, the second conductive portion, and the third conductive portion is zero,
the third frequency corresponding to a second excited state of the first structure when the magnetic flux is zero, and
the first frequency corresponding to the second excited state when the magnetic flux is 0.5 times a magnetic flux quantum.
(Technical proposal 2)

The electronic circuit according to Technical proposal 1, wherein
the first structure further includes a base,
the base includes a first face and a first side face crossing a plane including the first face,
the third Josephson junction is provided on the first face, and
at least a part of the first conductive portion is provided on the first side face.
(Technical proposal 3)

The electronic circuit according to Technical proposal 1 or 2, wherein
a third capacitance between the first conductive portion and the second conductive portion is greater than 0.2 times a first capacitance between the first conductive portion and the third conductive portion, and
the third capacitance is greater than 0.2 times a second capacitance between the second conductive portion and the third conductive portion.
(Technical proposal 4)

The electronic circuit according to Technical proposal 3, wherein
the third capacitance is 0.3 times or more the first capacitance, and
the third capacitance is 0.3 times or more the second capacitance.
(Technical proposal 5)

The electronic circuit according to any one of Technical proposals 1-4, wherein
the first frequency is not less than 1 GHz and not more than 20 GHz,
the second frequency is not less than 1 GHz and not more than 20 GHz, and
the third frequency is not less than 1 GHz and not more than 20 GHz.
(Technical proposal 6)

The electronic circuit according to any one of Technical proposals 1-5, wherein
an absolute value of a difference between half of the sum and the first frequency is 0.5 GHz or more.
(Technical proposal 7)

A computing device, comprising:
the electronic circuit according to Technical proposal 1 or 2;
a first qubit configured to be coupled with the first conductive portion; and
a second qubit configured to be coupled with the second conductive portion.
(Technical proposal 8)

The computing device according to Technical proposal 7, wherein
a third capacitance between the first conductive portion and the second conductive portion is greater than 3 times a fourth capacitance between the first conductive portion and the first qubit, and
the third capacitance is greater than 3 times a fifth capacitance between the second conductive portion and the second qubit.
(Technical proposal 9)

The computing device according to Technical proposal 8, wherein
the third capacitance is greater than 4.6 times the fourth capacitance, and
the third capacitance is greater than 4.6 times the fifth capacitance.
(Technical proposal 10)

The computing device according to any one of Technical proposals 7-9, further comprising:
a controller,
the first structure further including a first conductive member, and
the controller being configured to supply a signal to the first conductive member to control the magnetic flux in the space.
(Technical proposal 11)

The computing device according to Technical proposal 10, wherein
the signal includes a positive polarity signal and a negative polarity signal, and
the controller is configured to perform a two-qubit gate on the first qubit and the second qubit.
(Technical proposal 12)

The computing device according to Technical proposal 10 or 11, further comprising:
a high-pass filter provided between the controller and the first conductive member.
(Technical proposal 13)

The computing device according to any one of Technical proposals 7-12, wherein
the first qubit includes a fourth Josephson junction including a fourth end and a fourth other end,
the fourth other end is configured to be coupled with the first conductive portion, and
the fourth end is configured to be coupled with the third conductive portion.
(Technical proposal 14)

The computing device according to Technical proposal 13, wherein
the first qubit further includes a fourth conductive portion,
the fourth other end is electrically connected to the fourth conductive portion, and
the fourth conductive portion is configured to be coupled with the first conductive portion.
(Technical proposal 15)

The computing device according to Technical proposal 14, wherein
the first conductive portion includes:
   a first facing portion facing the second conductive portion; and
   a first other facing portion facing the fourth conductive portion,
the first facing portion and the first other facing portion satisfy at least one of the first condition or the second condition,
in the first condition, an area of the first facing portion is larger than an area of the first other facing portion, and
in the second condition, a first distance between the first facing portion and the second conductive portion is shorter than a second distance between the first other facing portion and the fourth conductive portion.
(Technical proposal 16)

The computing device according to any one of Technical proposals 7-12, wherein
the first qubit includes a fourth Josephson junction including a fourth end and a fourth other end,
the fourth other end is configured to be coupled with the first conductive portion,
the fourth end is configured to be coupled with the third conductive portion
the first qubit further includes a fourth conductive portion,
the fourth other end is electrically connected to the fourth conductive portion,
the fourth conductive portion is configured to be coupled with the first conductive portion,
the first conductive portion includes:
   a first facing portion facing the second conductive portion; and
   a first other facing portion facing the fourth conductive portion,
the first facing portion and the first other facing portion satisfy at least one of a first condition or a second condition,
in the first condition, an area of the first facing portion is larger than an area of the first other facing portion,
in the second condition, a first distance between the first facing portion and the second conductive portion is shorter than a second distance between the first other facing portion and the fourth conductive portion.
(Technical proposal 17)

The computing device according to any one of Technical proposals 7-16, wherein
the second qubit includes a fifth Josephson junction including a fifth end and a fifth other end,
the fifth other end is configured to be coupled with the second conductive portion, and
the fifth end is configured to be coupled with the third conductive portion.
(Technical proposal 18)

The computing device according to Technical proposal 17, wherein
the second qubit further includes a fifth conductive portion,
the fifth other end is electrically connected to the fifth conductive portion, and
the fifth conductive portion is configured to be coupled with the second conductive portion.
(Technical proposal 19)

The computing device according to Technical proposal 18, wherein
the second conductive portion includes:
   a second facing portion facing the first conductive portion; and
   a second other facing portion facing the fifth conductive portion,
the second facing portion and the second other facing portion satisfy at least one of a third condition or a fourth condition,
in the third condition, an area of the second facing portion is larger than an area of the second other facing portion, and
in the fourth condition, a third distance between the second facing portion and the fifth conductive portion is shorter than a fourth distance between the second other facing portion and the third conductive portion.
(Technical proposal 20)

The computing device according to any one of Technical proposals 7-16, wherein
the second qubit includes a fifth Josephson junction including a fifth end and a fifth other end,
the fifth other end is configured to be coupled with the second conductive portion,
the fifth end is configured to be coupled with the third conductive portion,
the second qubit further includes a fifth conductive portion,
the fifth other end is electrically connected to the fifth conductive portion,
the fifth conductive portion is configured to be coupled with the second conductive portion,
the second conductive portion includes:
   a second facing portion facing the first conductive portion; and
   a second other facing portion facing the fifth conductive portion,
the second facing portion and the second other facing portion satisfy at least one of a third condition or a fourth condition,
in the third condition, an area of the second facing portion is larger than an area of the second other facing portion, and
in the fourth condition, a third distance between the second facing portion and the fifth conductive portion is shorter than a fourth distance between the second other facing portion and the third conductive portion.

The third capacitance C3 between the first conductive portion 11c and the second conductive portion 12c is preferably greater than 1.5 times the fourth capacitance C4 between the first conductive portion 11c and the first qubit 50A. The third capacitance C3 is preferably greater than 1.5 times the fifth capacitance C5 between the second conductive portion 12c and the second qubit 50B.

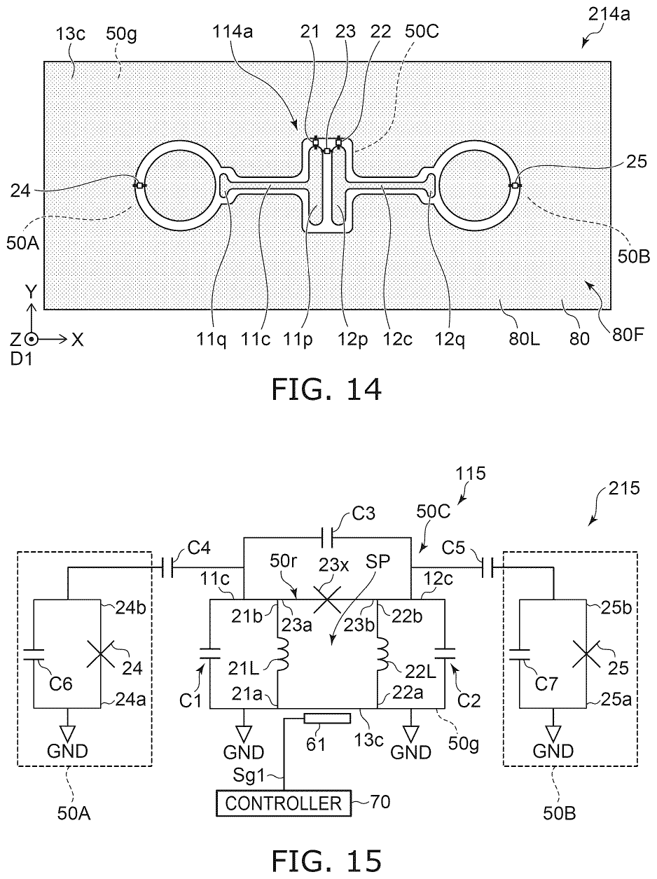

FIG. 14 is a schematic plan view illustrating an electronic circuit according to the embodiment.

As shown in FIG. 14, in an electronic circuit 114a according to the embodiment and in a computing device 214a including the electronic circuit 114a, a first structure 50C is provided on a base 80.

### Third Embodiment

FIG. 15 is a schematic diagram illustrating an electronic circuit according to a third embodiment.

As shown in FIG. 15, in an electronic circuit 115 and a computing device 215 according to the embodiment, the first structure 50C includes a first inductor 21L, a second inductor 22L, and an intermediate Josephson junction 23x instead of the first Josephson junction 21, the second Josephson junction 22, and the third Josephson junction 23. Except for this, the configuration of the electronic circuit 115 may be the same as the configuration of the electronic circuit 110.

In the electronic circuit 115, the first structure 50C includes:
a first inductor 21L including a first end 21a and a first other end 21b;
a second inductor 22L including a second end 22a and a second other end 22b;
an intermediate Josephson junction 23x including a third end 23a and a third other end 23b;
a first conductive portion 11c configured to couple with the first other end 21b and the third end 23a;
a second conductive portion 12c configured to couple with the second other end 22b and the third other end 23b; and
a third conductive portion 13c configured to couple with the first end 21a and the second end 22a.

In the electronic circuit 115 as well, half of the sum of the second frequency f2 and the third frequency f3 is less than the first frequency f1. The second frequency f2 corresponds to the first excited state E1 of the first structure 50C when the magnetic flux Φ passing through the space SP surrounded by the loop 50r including the first inductor 21L, the second inductor 22L, the intermediate Josephson junction 23x, the first conductive portion 11c, the second conductive portion 12c, and the third conductive portion 13c is zero. The third frequency f3 corresponds to the second excited state E2 of the first structure 50C when the magnetic flux Φ is zero. The first frequency f1 corresponds to the second excited state E2 when the magnetic flux Φ is 0.5 times the magnetic flux quantum.

The first inductor 21L may include one or more Josephson junctions. The plurality of Josephson junctions included in the first inductor 21L are connected in series. The second inductor 22L may include one or more Josephson junctions. The plurality of Josephson junctions included in the second inductor 22L are connected in series.

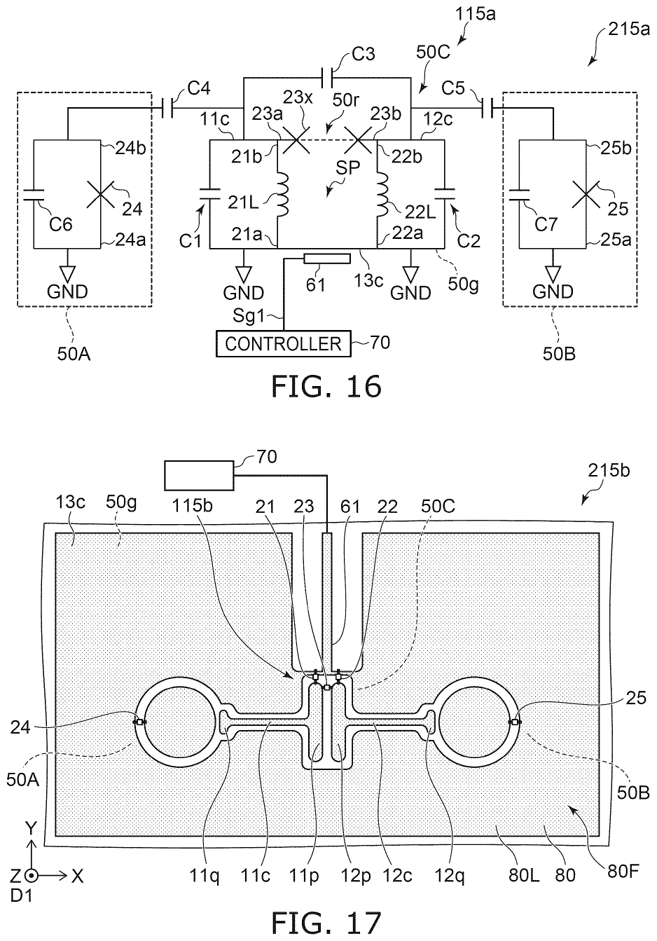

FIG. 16 is a schematic diagram illustrating an electronic circuit according to the third embodiment.

As shown in FIG. 16, in an electronic circuit 115a and a computing device 215a according to the embodiment, the first structure 50C includes a plurality of intermediate Josephson junctions 23x. Except for this, the configuration of the electronic circuit 115a may be the same as the configuration of the electronic circuit 115. The plurality of intermediate Josephson junctions 23x are connected in series.

### Fourth Embodiment

FIG. 17 is a schematic plan view illustrating an electronic circuit according to a fourth embodiment.

As shown in FIG. 17, in an electronic circuit 115b and a computing device 215b according to the embodiment, the first conductive member 61 is provided on the base 80.

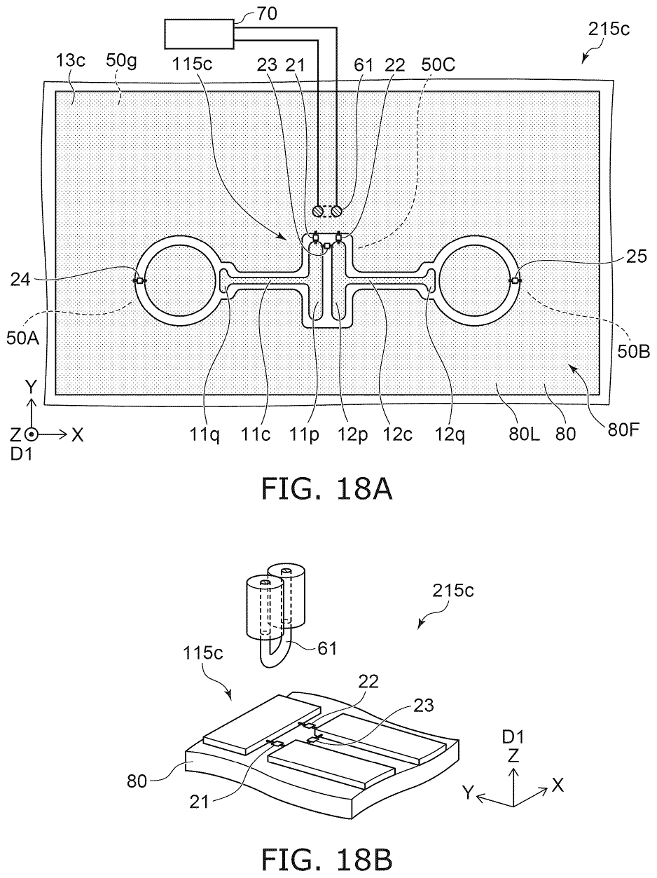

FIGS. 18A and 18B are schematic views illustrating an electronic circuit according to the fourth embodiment.

FIG. 18A is a plan view. FIG. 18B is a perspective view. As shown in FIGS. 18A and 18B, in an electronic circuit 115c and a computing device 215c according to the embodiment, the first conductive member 61 is provided away from the base 80.

### Fifth Embodiment

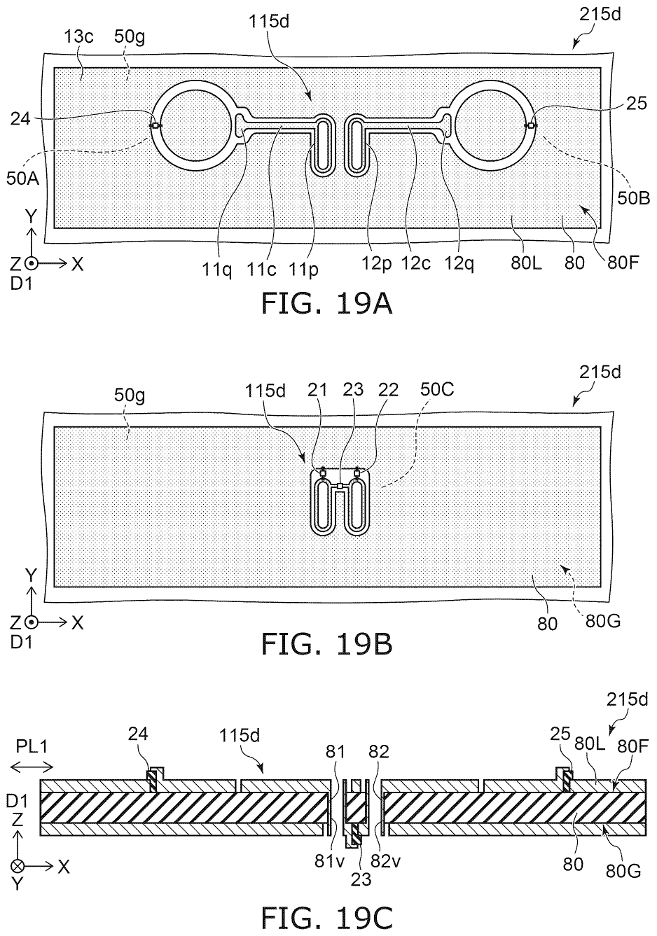

FIGS. 19A to 19C are schematic views illustrating an electronic circuit according to a fifth embodiment.

FIG. 19A is a plan view. FIG. 19B is a transparent plan view. FIG. 19C is a cross-sectional view. As shown in FIGS. 19A to 19C, in an electronic circuit 115d according to the embodiment and a computing device 215d, a fourth Josephson junction 24 and a fifth Josephson junction 25 are provided on a first face 80F of the base 80. The first Josephson junction 21, the second Josephson junction 22, and the third Josephson junction 23 are provided on a second face 80G of the base 80. A direction from the second face 80G to the first face 80F is along a first direction D1.

In this example, a conductive layer is provided on the first side face 81 of the base 80, and a first penetrating electrode 81v is formed by this conductive layer. A conductive layer is provided on a second side face 82 of the base 80, and a second penetrating electrode 82v is formed by this conductive layer. By these penetrating electrodes, the conductive member on the first face 80F and the conductive member on the second face 80G are electrically connected. The penetrating electrode may be, for example, a through-silicon via (TSV).

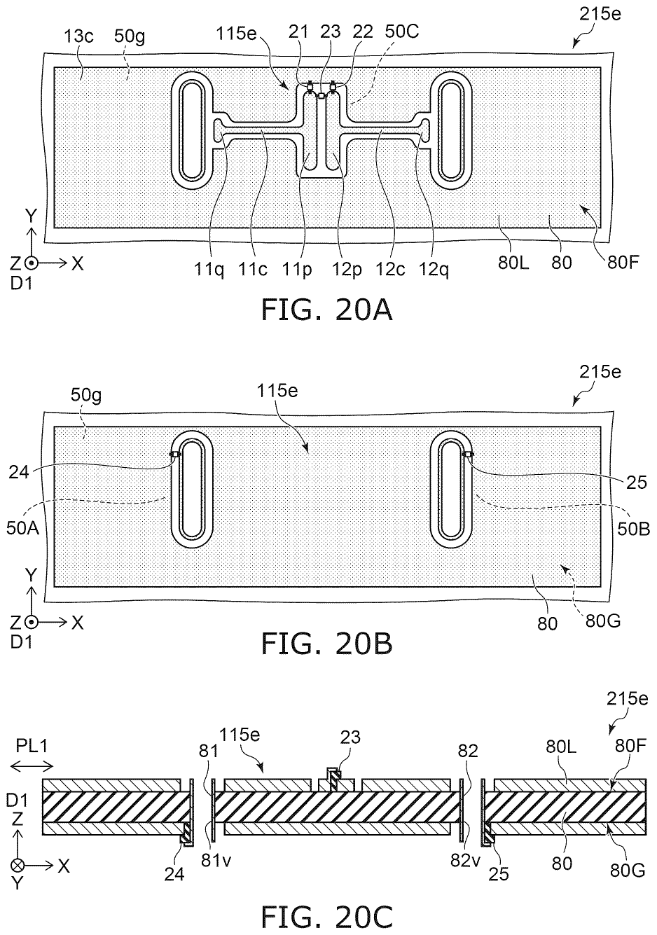

FIGS. 20A to 20C are schematic views illustrating an electronic circuit according to the fifth embodiment.

FIG. 20A is a plan view. FIG. 20B is a transparent plan view. FIG. 20C is a cross-sectional view. As shown in FIGS. 20A to 20C, in an electronic circuit 115e and a computing device 215e according to the embodiment, the first Josephson junction 21, the second Josephson junction 22, and the third Josephson junction 23 are provided on the first face 80F of a base 80. The fourth Josephson junction 24 and the fifth Josephson junction 25 are provided on the second face 80G of the base 80.

In this example, a conductive layer is provided on the first side face 81 of the base 80, and a first penetrating electrode 81v is formed by this conductive layer. A conductive layer is provided on the second side face 82 of the base 80, and a second penetrating electrode 82v is formed by this conductive layer. By these penetrating electrodes, the conductive member on the first face 80F and the conductive member on the second face 80G are electrically connected.

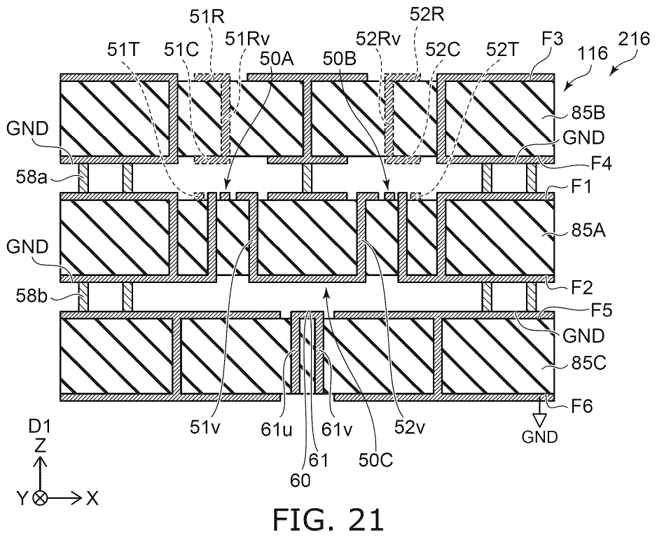

FIG. 21 is a schematic cross-sectional view illustrating an electronic circuit according to the fifth embodiment.

As shown in FIG. 21, an electronic circuit 116 according to the embodiment includes, a second base 85B, a first opposing electrode 51C, and a second opposing electrode 52C in addition to the first base 85A. Except for these, the configuration of the electronic circuit 116 may be the same as the configuration of the electronic circuit 110. A computing device 216 includes the electronic circuit 116.

In this example, the first base 85A includes a first face F1 and a second face F2. A direction from the second face F2 to the first face F1 is along the first direction D1. The first qubit 50A and the second qubit 50B are provided on the first face F1. The first structure 50C is provided on the second face F2. A first element terminal 51T coupled to the first qubit 50A is provided on the first face F1. A second element terminal 52T coupled to the second qubit 50B is provided on the first face F1.

The second base 85B includes a third face F3 and a fourth face F4. The fourth face F4 faces the first face F1 of the first base 85A. The fourth face F4 is between the first face F1 and the third face F3. The fourth face F4 is, for example, the lower face. The third face F3 is, for example, the upper face. A direction from the fourth face F4 to the third face F3 is along the first direction D1.

A first opposing electrode 51C is provided on the fourth face F4. A second opposing electrode 52C is provided on the fourth face F4. The first opposing electrode 51C can be coupled (e.g., capacitively coupled) with the first element terminal 51T. The second opposing electrode 52C can be coupled (e.g., capacitively coupled) with the second element terminal 52T.

A first readout electrode 51R, a first readout conductive portion 51Rv, a second readout electrode 52R, and a second readout conductive portion 52Rv may be provided. The first readout electrode 51R and the second readout conductive portion 52Rv are provided on the third face F3. The first readout conductive portion 51Rv extends in the second base 85B along the first direction D1. The first readout conductive portion 51Rv electrically connects the first opposing electrode 51C to the first readout electrode 51R. The second readout conductive portion 52Rv extends in the second base 85B along the first direction D1. The second readout conductive portion 52Rv electrically connects the second opposing electrode 52C to the second readout electrode 52R.

For example, the first readout electrode 51R and the second readout electrode 52R may be connected to the controller 70. The controller 70 (see FIG. 1) can obtain a signal corresponding to the state of the first qubit 50A and a signal corresponding to the state of the second qubit 50B via these electrodes.

As shown in FIG. 21, the electronic circuit 116 may include a third base 85C. The third base 85C includes a fifth face F5 and a sixth face F6. The fifth face F5 faces the second face F2. The fifth face F5 is between the sixth face F6 and the second face F2. The fifth face F5 is, for example, the upper face. The sixth face F6 is, for example, the lower face. A direction from the sixth face F6 to the fifth face F5 is along the first direction D1.

The electronic circuit 116 includes a magnetic flux controller 60. The magnetic flux controller 60 is provided on the fifth face F5. The magnetic flux controller 60 is capable of controlling the magnetic flux Φ in the space SP in the loop 50r (see FIG. 1). For example, a controller 70 is provided. The controller 70 controls the magnetic flux controller 60 to control the magnetic flux Φ.

In this example, the magnetic flux controller 60 includes the first conductive member 61. In this example, the electronic circuit 116 includes a first control conductive portion 61u and a second control conductive portion 61v.

As shown in FIG. 21, the first conductive member 61 is provided on the fifth face F5. The first control conductive portion 61u extends in the third base 85C along the first direction D1. The first control conductive portion 61u is electrically connected to a part of the first conductive member 61. The second control conductive portion 61v extends in the third base 85C along the first direction D1. The second control conductive portion 61v is electrically connected to another part of the first conductive member 61.

The controller 70 is connected to the first conductive member 61 via the first control conductive portion 61u and the second control conductive portion 61v. A magnetic field is generated by a signal (current) supplied from the controller 70 to the first conductive member 61. The generated magnetic field is applied to the space SP in the loop 50r (see FIG. 1). The magnetic flux Φ in the space SP is controlled.

As shown in FIG. 21, the conductive layer of ground potential GND provided on the first face F1 and the conductive layer of ground potential GND provided on the fourth face F4 may be electrically connected by a connection portion 58a. The conductive layer of ground potential GND provided on the second face F2 and the conductive layer of ground potential GND provided on the fifth face F5 may be electrically connected by a connection portion 58b.

A conductive layer provided on the fifth face F5 and set to a fixed potential (e.g., ground potential GND) and a conductive layer provided on the sixth face F6 and set to a fixed potential (e.g., ground potential GND) may be electrically connected by a conductive member extending through the third base 85C along the first direction D1.

The electronic circuit 116 may include a first element conductive portion 51v and a second element conductive portion 52v. The first element conductive portion 51v extends in the first base 85A along the first direction D1. The first element conductive portion 51v is electrically connected to the first qubit 50A. Alternatively, the first element conductive portion 51v can be coupled (e.g., capacitively coupled) to the first qubit 50A.

The second element conductive portion 52v extends in the first base 85A along the first direction D1. The second element conductive portion 52v is electrically connected to the second qubit 50B. Alternatively, the second element conductive portion 52v can be coupled (e.g., capacitively coupled) to the second qubit 50B.

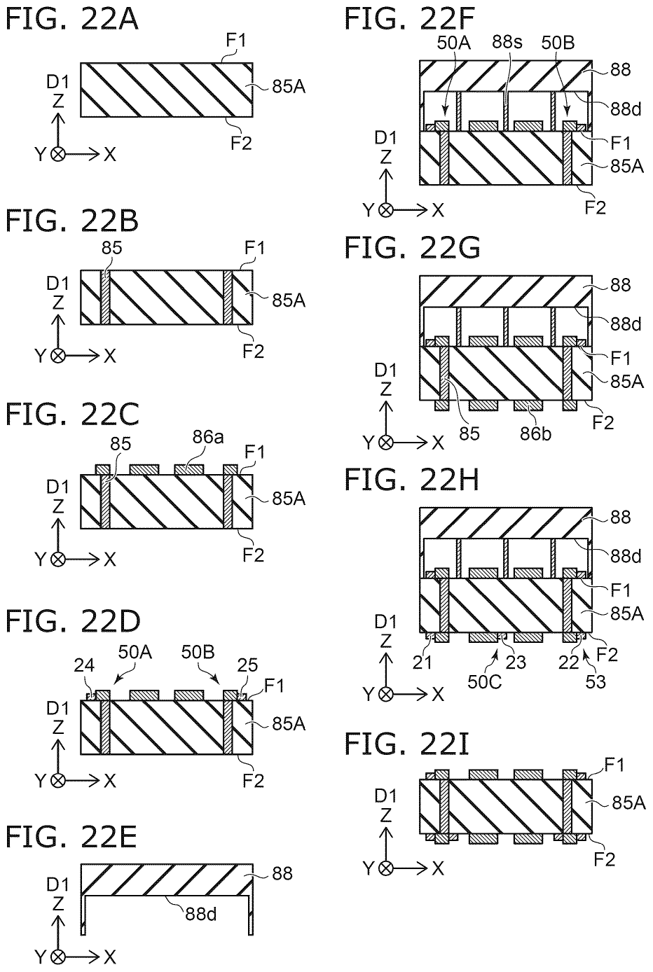

FIGS. 22A to 22I are schematic cross-sectional views illustrating a method for manufacturing an electronic circuit according to the fifth embodiment.

As shown in FIG. 22A, a first base 85A is prepared. The first base 85A includes a first face F1 and a second face F2.

As shown in FIG. 22B, a conductive portion 85 is formed on the first base 85A. The conductive portion 85 is along the first direction D1 from the second face F2 to the first face F1. The conductive portion 85 may be a TSV or the like. The conductive portion 85 may be the first element conductive portion 51v and the second element conductive portion 52v or the like.

As shown in FIG. 22C, a conductive member 86a is formed on the first face F1. The conductive member 86a may be at least a part of the capacitor included in the first qubit 50A and the second qubit 50B, etc. At least a part of the conductive member 86a is electrically connected to the conductive portion 85.

As shown in FIG. 22D, the fourth Josephson junction 24 and the fifth Josephson junction 25 are formed on the first face F1. In this manner, the first qubit 50A and the second qubit 50B are formed on the first face F1 of the first base 85A. The first qubit 50A includes the fourth Josephson junction 24. The second qubit 50B includes the fifth Josephson junction 25.

As shown in FIG. 22E, a first member 88 including a recess 88d is prepared. As shown in FIG. 22F, the first member 88 is provided. The first qubit 50A and the second qubit 50B are between the first base 85A and the recess 88d. A support portion 88s may be provided between the first face F1 and the recess 88d. The support portion 88s stabilizes the distance between the first face F1 and the recess 88d.

As shown in FIG. 22G, a conductive member 86b is formed on the second face F2. The conductive member 86b may be at least a part of a capacitor included in the first structure 50C, etc. At least a part of the conductive member 86b is electrically connected to the conductive portion 85.

As shown in FIG. 22H, the first Josephson junction 21, the second Josephson junction 22, and the third Josephson junction 23 are formed on the second face F2. These Josephson junctions are included in the first structure 50C. Thus, in this manufacturing method, the first structure 50C is formed on the second face F2 of the first base 85A. The first face F1 is between the second face F2 and the first member 88.

As shown in FIG. 22I, the first member 88 is removed. Thereby, an electronic circuit according to the embodiment can be obtained for example.

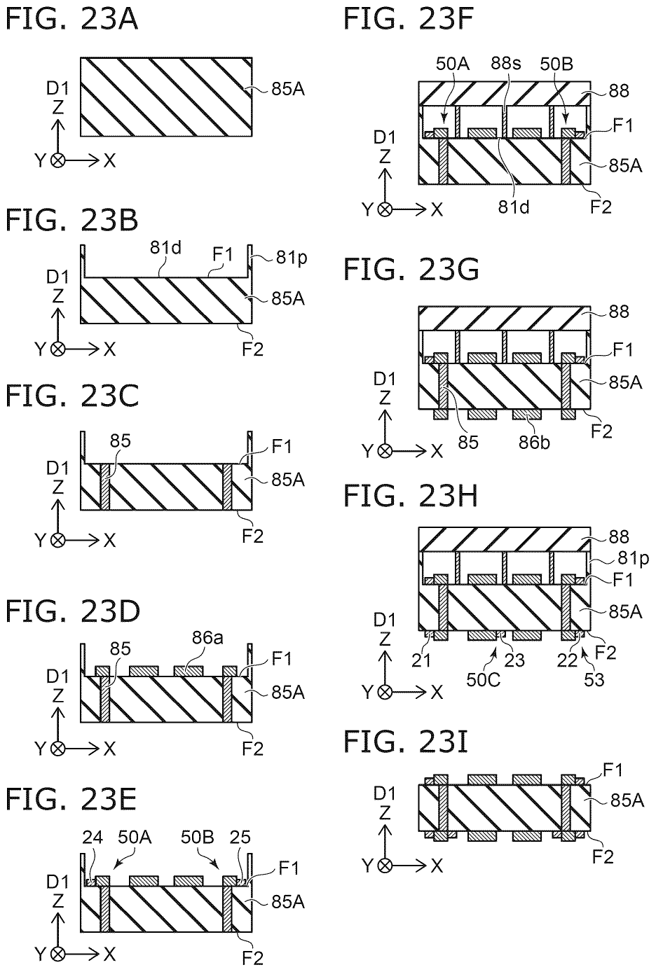

FIGS. 23A to 23I are schematic cross-sectional views illustrating a method for manufacturing an electronic circuit according to the fifth embodiment.

As shown in FIG. 23A, a substrate that will become the first base 85A is prepared. As shown in FIG. 23B, a recess 81d is formed in the first face F1 of the first base 85A. The first base 85A includes a second face F2. The first base 85A includes a protruding portion 81p around the recess 81d.

As shown in FIG. 23C, a conductive portion 85 is formed on the first base 85A. The conductive portion 85 is along the first direction D1 from the second face F2 to the first face F1. The conductive portion 85 may be a TSV or the like. The conductive portion 85 may be a first element conductive portion 51v and a second element conductive portion 52v or the like.

As shown in FIG. 23D, a conductive member 86a is formed on the first face F1. The conductive member 86a may be at least a part of the capacitor included in the first qubit 50A and the second qubit 50B. At least a part of the conductive member 86a is electrically connected to the conductive portion 85.

As shown in FIG. 23E, the fourth Josephson junction 24 and the fifth Josephson junction 25 are formed on the first face F1. In this manner, the first qubit 50A and the second qubit 50B are formed on the first face F1 of the first base 85A. The first qubit 50A includes the fourth Josephson junction 24. The second qubit 50B includes the fifth Josephson junction 25.

As shown in FIG. 23F, a first member 88 is provided. The first qubit 50A and the second qubit 50B are between the first base 85A and the first member 88. A support portion 88s may be provided between the recess 81d of the first face F1 and the first member 88. The support portion 88s stabilizes the distance between the recess 81d and the first member 88.

As shown in FIG. 23G, a conductive member 86b is formed on the second face F2. The conductive member 86b may be at least a part of a capacitor included in the first structure 50C, etc. At least a part of the conductive member 86b is electrically connected to the conductive portion 85.

As shown in FIG. 23H, the first Josephson junction 21, the second Josephson junction 22, and the third Josephson junction 23 are formed on the second face F2. Thus, in this manufacturing method, the first structure 50C is formed on the second face F2 of the first base 85A. The first face F1 is between the second face F2 and the first member 88.

As shown in FIG. 23I, the first member 88 is removed. Furthermore, the protruding portion 81p of the first base 85A is removed. Thereby, an electronic circuit according to the embodiment can be obtained for example.

### Sixth Embodiment

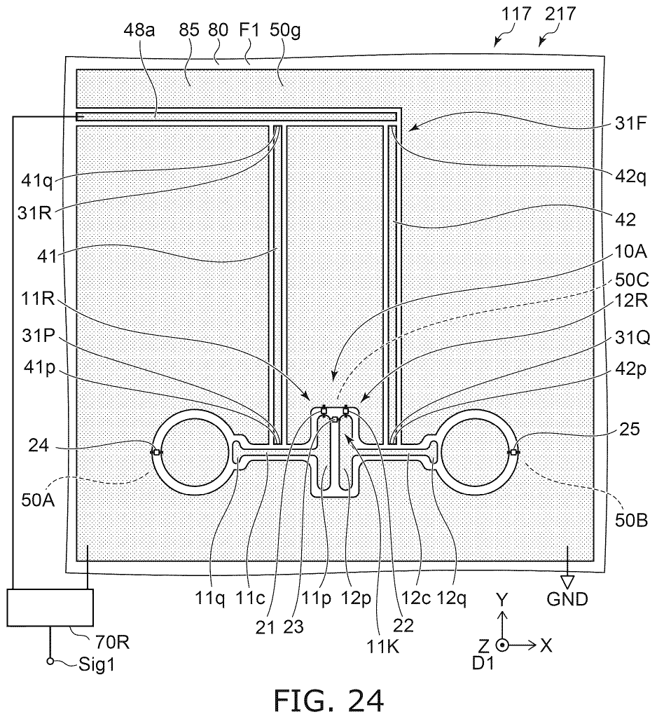

FIG. 24 is a schematic view illustrating an electronic circuit according to a sixth embodiment.

As shown in FIG. 24, an electronic circuit 117 according to the embodiment includes the first qubit 50A, the second qubit 50B, the first structure 50C (first coupler 10A), a first readout conductive member 48a, and a first filter 31F. The first coupler 10A may correspond to the first structure 50C. A computing device 217 includes the electronic circuit 117.

The first coupler 10A includes a first resonator 11R and a second resonator 12R. The first resonator 11R can be coupled to the first qubit 50A. The second resonator 12R can be coupled to the second qubit 50B. For example, the first resonator 11R can be electromagnetically coupled to the first qubit 50A. For example, the second resonator 12R can be electromagnetically coupled to the second qubit 50B. The electromagnetic coupling includes, for example, capacitive coupling. The electromagnetic coupling includes, for example, inductive coupling. The first coupler 10A is, for example, a tunable coupler.

The first filter 31F includes a first filter portion 31P, a first other filter portion 31Q, and a first readout portion 31R. The first filter portion 31P can be coupled to the first resonator 11R. The first other filter portion 31Q can be coupled to the second resonator 12R. The first readout portion 31R can be coupled to the first readout conductive member 48a. The first filter 31F may be, for example, a Purcell filter.

In this embodiment, the state of the qubit is read out by the first readout conductive member 48a via the first filter 31F. Thereby, qubits and couplers can be provided at a high density, for example.

In the embodiment, the resonator included in the first coupler 10A is coupled to the first filter 31F. The state of the qubit is read out via the coupler and the first filter 31F. In the embodiment, the readout resonator can be omitted. This enables space saving and high-density qubit arrangement. According to the embodiment, an electronic circuit capable of improving characteristics can be provided.

As shown in FIG. 24, in this example, the first filter 31F includes a first conductive component 41 and a second conductive component 42. The first conductive component 41 includes a first conductive portion 41p and a first other conductive portion 41q. The second conductive component 42 includes a second conductive portion 42p and a second other conductive portion 42q. The first conductive portion 41p can be coupled to the first resonator 11R. The second conductive portion 42p can be coupled to the second resonator 12R. The first other conductive portion 41q can be coupled to the first readout conductive member 48a. The second other conductive portion 42q can be coupled to the first readout conductive member 48a.

The first conductive portion 41p corresponds to the first filter portion 31P. The second conductive portion 42p corresponds to the first other filter portion 31Q. At least one of the first other conductive portion 41q or the second other conductive portion 42q corresponds to the first readout portion 31R.

The first qubit 50A, the second qubit 50B, the first coupler 10A, the first readout conductive member 48a and the first filter 31F may be formed, for example, by a conductive portion 85 (e.g., a conductive layer) provided on the first face F1 of the base 80.

As shown in FIG. 24, the first coupler 10A includes a third Josephson junction 23 (for example, a first coupler Josephson junction 11K). One end of the third Josephson junction 23 (first coupler Josephson junction 11K) is connected to the first resonator 11R. The other end of the third Josephson junction 23 (first coupler Josephson junction 11K) is connected to the second resonator 12R.

The first resonator 11R includes a first Josephson junction 21. The second resonator 12R includes a second Josephson junction 22. The first Josephson junction 21 may be the first inductor 21L already described. The second Josephson junction 22 may be the second inductor 22L already described.

The first resonator 11R is, for example, a first transmon resonator. The second resonator 12R is, for example, a second transmon resonator. The first coupler 10A is, for example, a double-transmon coupler.

A conductive portion is provided that is connected to the first Josephson junction 21 (e.g., the first inductor 21L). A conductive portion is provided that is connected to the second Josephson junction 22 (e.g., the second inductor 22L).

The first filter portion 31P of the first filter 31F can be coupled to a conductive portion connected to the first Josephson junction 21. The first other filter portion 31Q of the first filter 31F can be coupled to a conductive portion connected to the second Josephson junction 22. The first Josephson junction 21 and the conductive portion connected to the first Josephson junction 21 are included in the first resonator 11R. The second Josephson junction 22 and the conductive portion connected to the second Josephson junction 22 are included in the second resonator 12R.

As shown in FIG. 24, the first qubit 50A includes the fourth Josephson junction 24, and the second qubit 50B includes the fifth Josephson junction 25.

The conductive portion connected to the fourth Josephson junction 24 can be coupled to a conductive portion connected to the first Josephson junction 21 (e.g., the first inductor 21L). The conductive portion connected to the fourth Josephson junction 24 can be coupled to a conductive portion connected to the second Josephson junction 22 (e.g., the second inductor 22L).

A part of the conductive portion 85 (conductive layer) provided on the first face F1 of the base 80 may function as a ground layer 50g. The ground layer 50g is set to a ground potential GND (e.g., a reference potential). For example, the ground layer 50g may be provided around the conductive portion 85 (conductive layer) that forms the first qubit 50A, the second qubit 50B, the first coupler 10A, the first readout conductive member 48a, and the first filter 31F.

As shown in FIG. 24, a readout circuit 70R may be provided. For example, the readout circuit 70R may be included in the electronic circuit 117. The readout circuit 70R may be provided separately from the electronic circuit 117. The readout circuit 70R is electrically connected to the first readout conductive member 48a. The readout circuit 70R can detect the state of the first qubit 50A and the state of the second qubit 50B based on the signal obtained from the first readout conductive member 48a. For example, the readout circuit 70R detects an output signal based on the input signal input to the first readout conductive member 48a. Thereby, it becomes possible to detect the state of the first qubit 50A and the state of the second qubit 50B. The readout circuit 70R outputs an output signal Sig1 including the detection result.

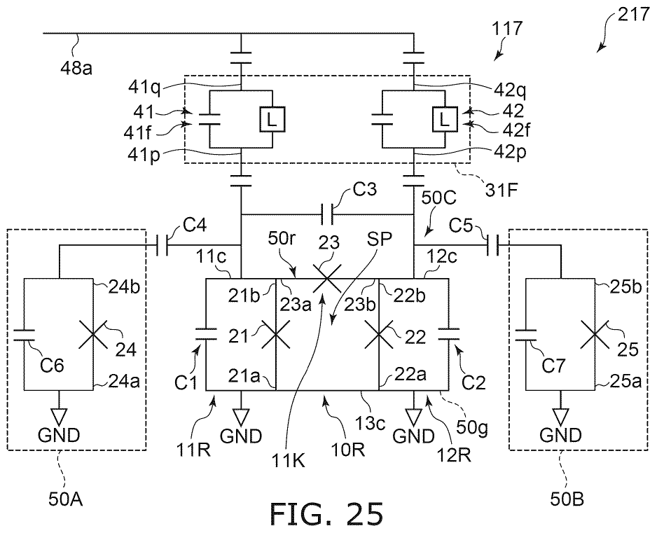

FIG. 25 is a circuit diagram illustrating an electronic circuit according to the sixth embodiment.

As shown in FIG. 25, the first resonator 11R includes a first Josephson junction 21 (e.g., a first inductor 21L) and a first capacitor (a first capacitance C1). The first capacitance C1 is connected in parallel with the first Josephson junction 21 (e.g., the first inductor 21L).

The second resonator 12R includes a second Josephson junction 22 (e.g., a second inductor 22L) and a second capacitor (a second capacitance C2). The second capacitance C2 is connected in parallel with the second Josephson junction 22 (e.g., the second inductor 22L).

The first coupler 10A further includes a third Josephson junction 23 (for example, the first coupler Josephson junction 11K). One end of the third Josephson junction 23 (for example, the first coupler Josephson junction 11K) is connected to one end of the first Josephson junction 21 and one end of the first capacitor (first capacitance C1). The other end of the third Josephson junction 23 (for example, the first coupler Josephson junction 11K) is connected to one end of the second Josephson junction 22 and one end of the second capacitor (second capacitance C2).

The other end of the first Josephson junction 21 and the other end of the first capacitor (first capacitance C1) are set to ground potential GND. The other end of the second Josephson junction 22 and the other end of the second capacitor (second capacitance C2) are set to ground potential GND.

The first qubit 50A includes a fourth Josephson junction 24 and a sixth capacitor (sixth capacitance C6). The sixth capacitance C6 is connected in parallel with the fourth Josephson junction 24. One end of the fourth Josephson junction 24 and one end of the sixth capacitor (sixth capacitance C6) can be coupled to the first conductive portion 11c. The other end of the fourth Josephson junction 24 and the other end of the sixth capacitor (sixth capacitance C6) are set to the ground potential GND.

The second qubit 50B includes a fifth Josephson junction 25 and a seventh capacitor (seventh capacitance C7). The seventh capacitance C7 is connected in parallel with the fifth Josephson junction 25. One end of the fifth Josephson junction 25 and one end of the seventh capacitor (seventh capacitance C7) can be coupled to the second conductive portion 12c. The other end of the fifth Josephson junction 25 and the other end of the seventh capacitor (seventh capacitance C7) are set to the ground potential GND.

The first conductive component 41 can be regarded, for example, as an LC circuit connected in parallel. The first conductive component 41 corresponds, for example, to the first filter resonator 41f. The second conductive component 42 can be regarded, for example, as an LC circuit connected in parallel. The second conductive component 42 corresponds, for example, to the second filter resonator 42f. These LC circuits are waveguide resonators.

In one example, the resonant frequency of the first qubit 50A is approximately 8.3 GHz. The resonant frequency of the second qubit 50B is approximately 9.0 GHz. The resonant frequency of the first resonator 11R is approximately 11.0 GHz. The resonant frequency of the second resonator 12R is approximately 11.7 GHz. The frequency of the first resonator 11R is different from the resonant frequency of the second resonator 12R. The resonant frequencies of the first resonator 11R and the second resonator 12R are read out via the first filter 31F. The resonant frequency of the first qubit 50A and the resonant frequency of the second qubit 50B are substantially blocked by the first filter 31F.

In the embodiment, for example, the resonant frequency of the first resonator 11R is higher than the resonant frequency of the first qubit 50A. The resonant frequency of the second resonator 12R is higher than the resonant frequency of the second qubit 50B.

As shown in FIG. 25, a loop 50r is provided in a first coupler 10A. The loop 50r includes a conductive path including the first Josephson junction 21, a conductive path including the second Josephson junction 22, and a conductive path including the third Josephson junction 23. For example, by controlling the magnetic flux Φ in the loop 50r, it is possible to control the coupling strength between the first qubit 50A and the second qubit 50B.

For example, the coupling between the first qubit 50A and the second qubit 50B can be substantially turned off. This state is, for example, an idle state. In the idle state, the first resonator 11R can be considered as a resonator strongly coupled to the first qubit 50A. The first resonator 11R can function as a readout resonator. In the embodiment, a separately formed readout resonator is not required. A space-saving electronic circuit can be obtained.

For example, as the first filter resonator 41f and the second filter resonator 42f, transmons are used instead of linear resonators. In this case, the input of the transmons is sufficiently weakened. The first resonator 11R is strongly coupled to the first qubit 50A, resulting in a large state-dependent frequency shift. For example, with strong coupling, the state-dependent frequency shift is about 30 MHz and it becomes possible to read out the qubit state.

For example, if there is a loss of about 50% in the output signal, a read error probability of less than 1% can be obtained in a read period of 200 ns.

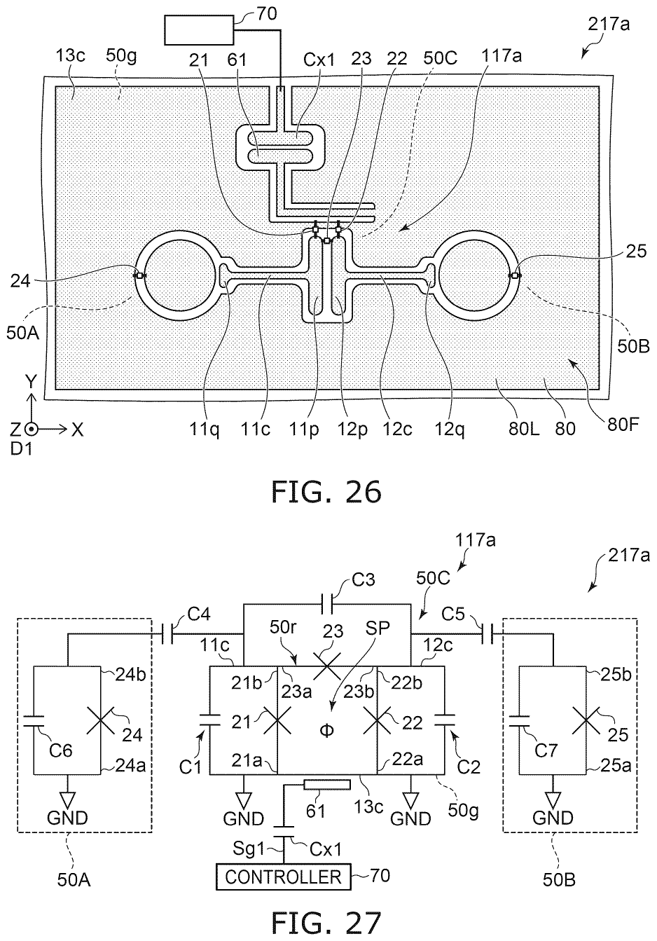

FIG. 26 is a schematic plan view illustrating an electronic circuit according to the sixth embodiment.

FIG. 27 is a schematic diagram illustrating the electronic circuit according to the sixth embodiment.

As shown in FIGS. 26 and 27, an electronic circuit 117a according to the embodiment includes the first conductive member 61. In the electronic circuit 117a, the first conductive member 61 is configured to be coupled to the controller 70 via a coupling capacitor (coupling capacitance Cx1). Except for this, the configuration of the electronic circuit 117a may be the same as the configuration of the electronic circuit 110. A computing device 217a includes the electronic circuit 117a.

### Seventh Embodiment

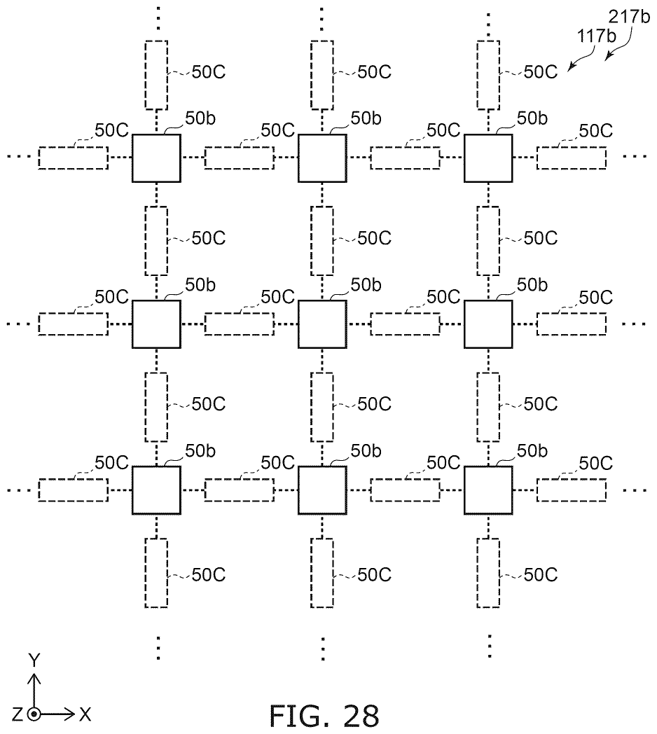

FIG. 28 is a schematic plan diagram illustrating an electronic circuit according to the seventh embodiment.

As shown in FIG. 28, an electronic circuit 117b according to the embodiment includes a plurality of qubits 50b and a plurality of first structures 50C. The plurality of first structures 50C correspond to couplers. The plurality of qubits 50b are arranged, for example, in a matrix on the X-Y plane. One of the plurality of first structures 50C is arranged between one of the plurality of qubits 50b and another one of the plurality of qubits 50b. One of the plurality of qubits 50b corresponds, for example, to the first qubit 50A. The other one of the plurality of qubits 50b corresponds, for example, to the second qubit 50B. One of the plurality of first structures 50C can be coupled (for example, capacitively coupled) to one of the plurality of qubits 50b. One of the plurality of first structures 50C can be coupled (e.g., capacitively coupled) to another one of the plurality of qubits 50b.

A computing device 217b according to the embodiment includes electronic circuit 117b. Any of the above electronic circuit configurations can be applied to computing device 217b. For example, Josephson junctions included in the plurality of qubits 50b are provided on the first face F1. Josephson junctions included in each of the plurality of first structures 50C may be provided on another face (such as the second face F2).

### Eighth Embodiment

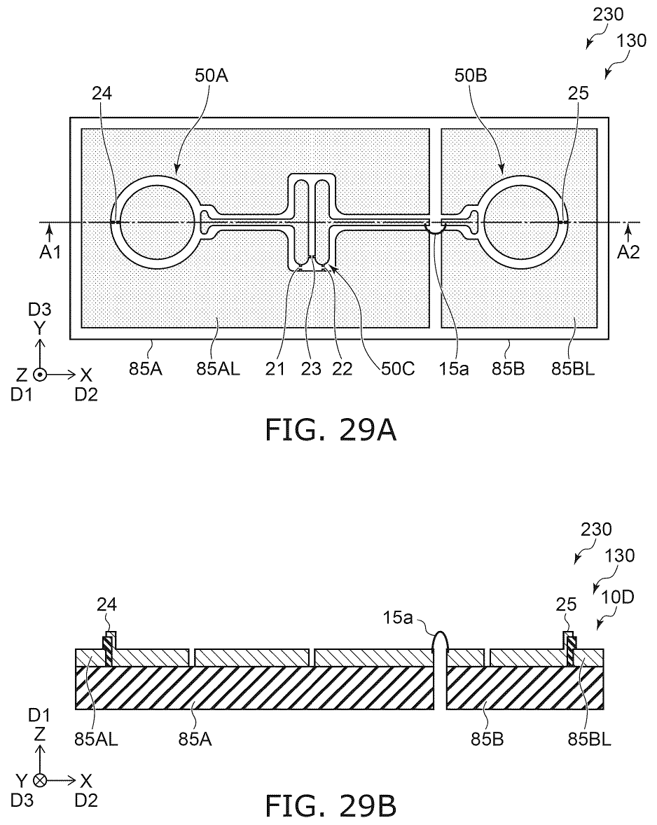

FIGS. 29A and 29B are schematic views illustrating a computing device according to the eighth embodiment.

FIG. 29B is a cross-sectional view taken along the line A1-A2 in FIG. 29A,

s shown in FIGS. 29A and 29B, an electronic circuit 130 according to the embodiment includes a first base 85A and a second base 85B. A computing device 230 includes the electronic circuit 130.

In the electronic circuit 130, the first qubit 50A and the first structure 50C are provided on the first base 85A. The second qubit 50B is provided on the second base 85B. The first structure 50C is coupled to the second qubit 50B via the first connection member 15a.

A first base conductive layer 85AL is provided on the first base 85A. A second base conductive layer 85BL is provided on the second base 85B. At least a part of the first qubit 50A may be formed by the first base conductive layer 85AL. At least a part of the first structure 50C may be formed by the first base conductive layer 85AL. At least a part of the second qubit 50B may be formed by the second base conductive layer 85BL.

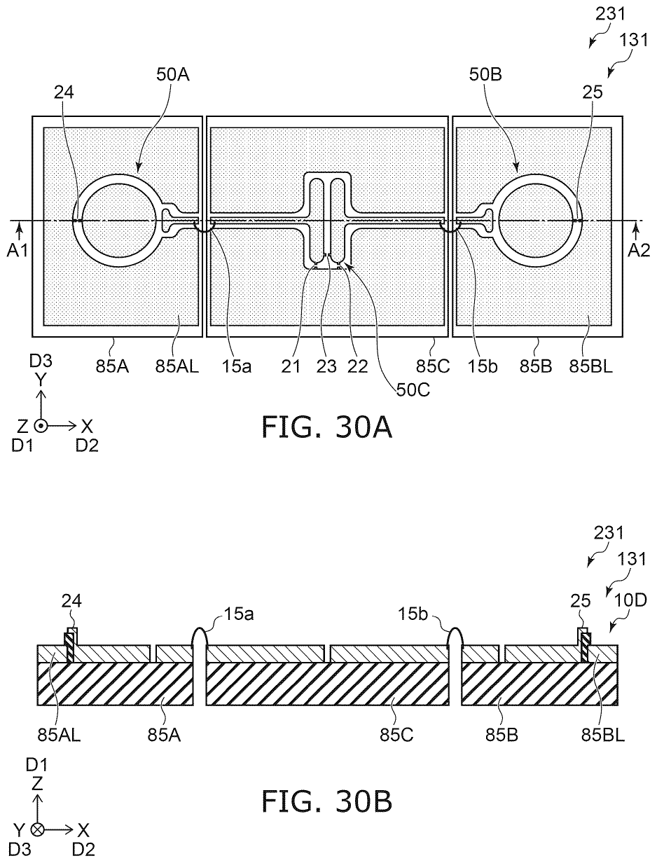

FIGS. 30A and 30B are schematic views illustrating a computing device according to the eighth embodiment.

FIG. 30B is a cross-sectional view taken along the line A1-A2 in FIG. 30A.

As shown in FIGS. 30A and 30B, in an electronic circuit 131 according to the embodiment, the first structure 50C is provided on a third base 85C. Except for this, the configuration of the electronic circuit 131 may be the same as the configuration of the electronic circuit 130. A computing device 231 includes an electronic circuit 131.

In the electronic circuit 131, the first qubit 50A is provided on the first base 85A. The second qubit 50B is provided on the second base 85B. The first structure 50C is coupled to the first qubit 50A via the first connection member 15a. The first structure 50C is coupled to the second qubit 50B via the second connection member 15b.

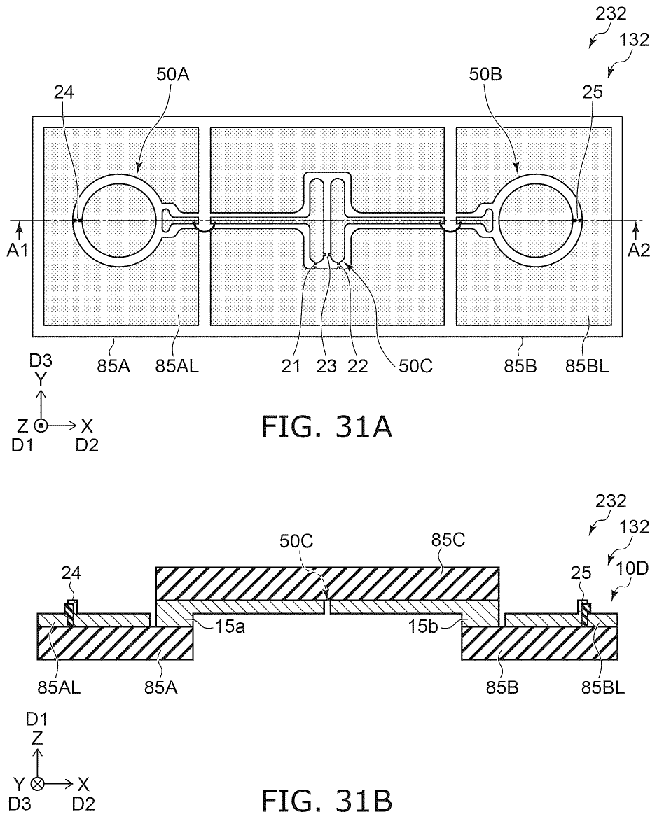

FIGS. 31A and 31B are schematic views illustrating a calculation device according to the eighth embodiment.

FIG. 31B is a cross-sectional view taken along the line A1-A2 in FIG. 31A.

As shown in FIGS. 31A and 31B, in an electronic circuit 132 according to the embodiment, the third base 85C overlaps the first base 85A and overlaps the second base 85B. Except for this, the configuration of the electronic circuit 132 may be the same as the configuration of the electronic circuit 131. A calculation device 232 includes the electronic circuit 132.

In the electronic circuit 132, the position of the conductive member included in the third base 85C in the first direction D1 is between the position of the first base 85A in the first direction D1 and the position of the third base 85C in the first direction D1. The position of the conductive member included in the third base 85C in the first direction D1 is between the position of the second base 85B in the first direction D1 and the position of the third base 85C in the first direction D1.

In the electronic circuit 132, the first structure 50C is coupled to the first qubit 50A provided on the first base 85A via the first connection member 15a. The first structure 50C is coupled to the second qubit 50B provided on the second base 85B via the second connection member 15b.

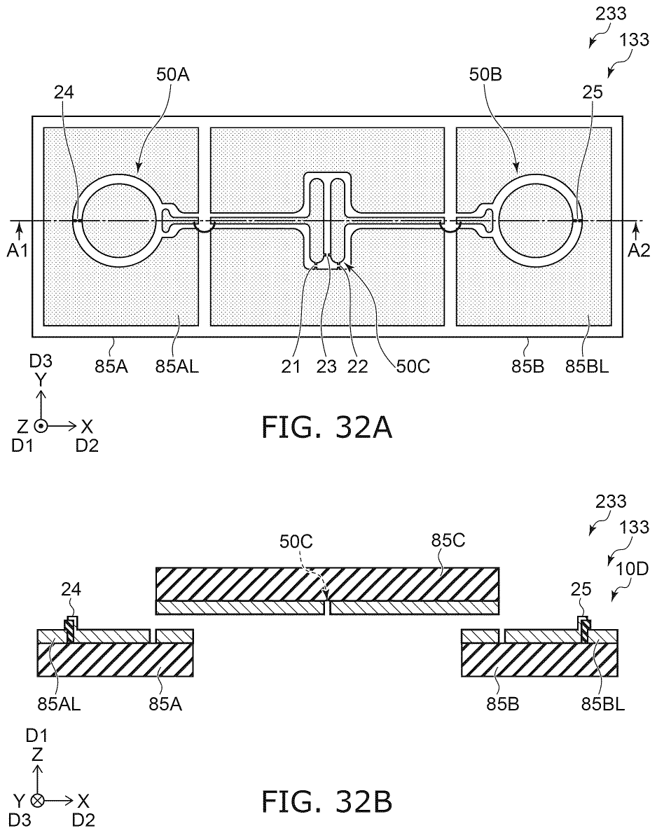

FIGS. 32A and 32B are schematic diagrams illustrating a calculation device according to the eighth embodiment.

FIG. 32B is a cross-sectional view taken along the line A1-A2 in FIG. 32A.

As shown in FIGS. 32A and 32B, in an electronic circuit 133 according to the embodiment, the connection members are omitted from the configuration of the electronic circuit 132. Except for this, the configuration of the electronic circuit 133 may be the same as the configuration of the electronic circuit 132. A calculation device 233 includes the electronic circuit 133.

In the electronic circuit 133, the first structure 50C provided on the third base 85C is coupled to the first qubit 50A provided on the first base 85A. The first structure 50C provided on the third base 85C is coupled to the second qubit 50B provided on the second base 85B. The coupling may be, for example, capacitive coupling.

According to the embodiments, it is possible to provide an electronic circuit and a computing device capable of improving characteristics.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the electronic circuits and computing devices such as structures, Josephson junctions, bases, conductive portions, controllers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all electronic circuits and all computing devices practicable by an appropriate design modification by one skilled in the art based on the electronic circuits and the computing devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An electronic circuit, comprising:
a first structure, the first structure including:
a first Josephson junction including a first end and a first other end;
a second Josephson junction including a second end and a second other end;
a third Josephson junction including a third end and a third other end;
a first conductive portion configured to be coupled with the first other end and the third end;
a second conductive portion configured to be coupled with the second other end and the third other end; and
a third conductive portion configured to be coupled to the first end and the second end,
½ of a sum of a second frequency and a third frequency being smaller than a first frequency,
the second frequency corresponding to a first excited state of the first structure when a magnetic flux passing through a space surrounded by a loop including the first Josephson junction, the second Josephson junction, the third Josephson junction, the first conductive portion, the second conductive portion, and the third conductive portion is zero,
the third frequency corresponding to a second excited state of the first structure when the magnetic flux is zero, and
the first frequency corresponding to the second excited state when the magnetic flux is 0.5 times a magnetic flux quantum.

2. The electronic circuit according to claim 1, wherein
the first structure further includes a base,
the base includes a first face and a first side face crossing a plane including the first face,
the third Josephson junction is provided on the first face, and
at least a part of the first conductive portion is provided on the first side face.

3. The electronic circuit according to claim 1, wherein
a third capacitance between the first conductive portion and the second conductive portion is greater than 0.2 times a first capacitance between the first conductive portion and the third conductive portion, and
the third capacitance is greater than 0.2 times a second capacitance between the second conductive portion and the third conductive portion.

4. A computing device, comprising:
the electronic circuit according to claim 1;
a first qubit configured to be coupled with the first conductive portion; and
a second qubit configured to be coupled with the second conductive portion.

5. The computing device according to claim 4, wherein
a third capacitance between the first conductive portion and the second conductive portion is greater than 1.5 times a fourth capacitance between the first conductive portion and the first qubit, and
the third capacitance is greater than 1.5 times a fifth capacitance between the second conductive portion and the second qubit.

6. The computing device according to claim 4, further comprising:
a controller,
the first structure further including a first conductive member, and
the controller being configured to supply a signal to the first conductive member to control the magnetic flux in the space.

7. The computing device according to claim 6, wherein
the signal includes a positive polarity signal and a negative polarity signal, and
the controller is configured to perform a two-qubit gate on the first qubit and the second qubit.

8. The computing device according to claim 6, further comprising:
a high-pass filter provided between the controller and the first conductive member.

9. The computing device according to claim 4, wherein
the first qubit includes a fourth Josephson junction including a fourth end and a fourth other end,
the fourth other end is configured to be coupled with the first conductive portion,
the fourth end is configured to be coupled with the third conductive portion,
the first qubit further includes a fourth conductive portion,
the fourth other end is electrically connected to the fourth conductive portion,
the fourth conductive portion is configured to be coupled with the first conductive portion,
the first conductive portion includes:
a first facing portion facing the second conductive portion; and
a first other facing portion facing the fourth conductive portion,
the first facing portion and the first other facing portion satisfy at least one of a first condition or a second condition,
in the first condition, an area of the first facing portion is larger than an area of the first other facing portion,
in the second condition, a first distance between the first facing portion and the second conductive portion is shorter than a second distance between the first other facing portion and the fourth conductive portion.

10. The computing device according to claim 4, wherein
the second qubit includes a fifth Josephson junction including a fifth end and a fifth other end,
the fifth other end is configured to be coupled with the second conductive portion,
the fifth end is configured to be coupled with the third conductive portion,
the second qubit further includes a fifth conductive portion,
the fifth other end is electrically connected to the fifth conductive portion,
the fifth conductive portion is configured to be coupled with the second conductive portion,
the second conductive portion includes:
a second facing portion facing the first conductive portion; and
a second other facing portion facing the fifth conductive portion,
the second facing portion and the second other facing portion satisfy at least one of a third condition or a fourth condition,
in the third condition, an area of the second facing portion is larger than an area of the second other facing portion, and
in the fourth condition, a third distance between the second facing portion and the fifth conductive portion is shorter than a fourth distance between the second other facing portion and the third conductive portion.

11. An electronic circuit, comprising:
a first structure, the first structure including
a first inductor including a first end and a first other end,
a second inductor including a second end and a second other end,
an intermediate Josephson junction including a third end and a third other end,
a first conductive portion configured to be coupled with the first other end and the third end,
a second conductive portion configured to be coupled with the second other end and the third other end, and
a third conductive portion configured to be coupled with the first end and the second end,
half of a sum of a second frequency and a third frequency being less than a first frequency,
the second frequency corresponding to a first excited state of the first structure when a magnetic flux passing through a space surrounded by a loop including the first inductor, the second inductor, the intermediate Josephson junction, the first conductive portion, the second conductive portion, and the third conductive portion is zero,
the third frequency corresponding to a second excited state of the first structure when the magnetic flux is zero;
the first frequency corresponding to the second excited state when the magnetic flux is 0.5 times a magnetic flux quantum.

12. A computing device comprising:
a first qubit;
a second qubit;
a first coupler including a first resonator and a second resonator, the first resonator being configured to be coupled with the first qubit, the second resonator being configured to be coupled with the second qubit;
a first readout conductive member; and
a first filter including a first filter portion, a first other filter portion, and a first readout portion, the first filter portion being configured to be coupled with the first resonator, the first other filter portion being configured to be coupled with the second resonator, and the first readout portion being configured to be coupled with the first readout conductive member.
